(19) United States
(12) Patent Application Publication
(10) Pub. No.: US 2025/0031400 A1
(43) Pub. Date: Jan. 23, 2025

(54) FORKSHEET SEMICONDUCTOR DEVICES AND METHODS OF FABRICATING THE SAME

(71) Applicant: Tokyo Electron Limited, Tokyo (JP)

(72) Inventors: Mark I. GARDNER, Austin, TX (US); Henry Jim FULFORD, Marianna, FL (US); Partha MUKHOPADHYAY, Oviedo, FL (US)

(73) Assignee: Tokyo Electron Limited, Tokyo (JP)

(21) Appl. No.: 18/224,940

(22) Filed: Jul. 21, 2023

(51) Int. Cl. H01L 29/775; H01L 29/06; H01L 29/423; H01L 29/51; H01L 29/66; H10B 51/20

(52) U.S. Cl. CPC H01L 29/775; H01L 29/0673; H01L 29/42392; H01L 29/516; H01L 29/6684; H10B 51/20

(57) ABSTRACT

A semiconductor structure includes a stack of channel layers extending vertically over a substrate. The semiconductor structure includes a gate structure interleaved with the stack, where the gate structure wraps around a first end of each channel layer. The gate structure includes a dielectric layer over the channel layer, a ferroelectric layer over the dielectric layer, and a metal layer over the ferroelectric layer. The semiconductor structure includes an isolation structure disposed over a second end of each channel layer opposite the first end.

### FIELD OF THE DISCLOSURE

This disclosure relates generally to semiconductor devices and methods of fabricating the same, and more specifically to semiconductor devices with a forksheet structure and methods of fabricating the same.

### BACKGROUND

In the manufacture of a semiconductor device (especially on the microscopic scale), various fabrication processes are executed such as film-forming depositions, etch mask creation, patterning, material etching and removal, and doping treatments. These processes are performed repeatedly to form desired semiconductor device elements on a substrate. Historically, with microfabrication, transistors have been created in one plane, with wiring/metallization formed above the active device plane, and have thus been characterized as two-dimensional (2D) circuits or 2D fabrication. Scaling efforts have greatly increased the number of transistors per unit area in 2D circuits, yet scaling efforts are running into greater challenges as scaling enters single digit nanometer semiconductor device fabrication nodes.

Semiconductor device fabricators have expressed a desire for three-dimensional (3D) semiconductor circuits in which spacings between transistors or channels thereof are reduced. This reduction in spacings can be prevalent especially in the integration of memory devices. While efforts of such integration have been generally adequate to overcome scaling limitations experienced in planar devices, they are not entirely satisfactory in all aspects.

### SUMMARY

The present disclosure relates to non-planar, or three-dimensional (3D), structures and transistors. The channel regions of the transistors may be oriented to conduct current through the channel in a direction generally parallel with the major surface of the system or chip upon which, or within which, these structures are provided. Multi-channel designs may be utilized to provide cost, performance, and/or design advantages. The techniques and structures described herein provide a higher density of devices using vertically stacked transistors or channels thereof, which allows for a higher 3D density.

One aspect of the present disclosure can be directed to a structure. The structure can include a stack of channel layers extending vertically over a substrate. The structure can include a gate structure interleaved with the stack, where the gate structure wraps around a first end of each channel layer. The structure can include an isolation structure disposed over a second end of each channel layer opposite the first end. The gate structure can include a dielectric layer over the channel layer, a ferroelectric layer over the dielectric layer, and a metal layer over the ferroelectric layer.

Another aspect of the present disclosure can be directed to a structure. The structure can a memory device. The memory device can include first channel layers stacked vertically over a substrate. The memory device can include a first gate structure interleaved with the first channel layers, where the first gate structure wraps around a first end of each first channel layer. The memory device can include a first dielectric layer extending vertically over a second end of each first channel layer opposite the first end. The first gate structure can include a first gate dielectric layer over the first channel layer, a first metal layer over the first gate dielectric layer, a ferroelectric layer over the first metal layer, and a second metal layer over the ferroelectric layer.

Yet another aspect of the present disclosure can be directed to a method. The method can include forming a stack including alternating first sacrificial layers and channel layers over a second sacrificial layer on a substrate. The method can include forming a first dielectric layer adjacent each sidewall of the stack. The method can include patterning the stack to form a first opening vertically extending through the stack to form first active structure adjacent a second active structure. The method can include forming a second dielectric layer to fill the first opening. The method can include selectively etching end portions of the first sacrificial layer to form second openings. The method can include forming a third dielectric layer to fill the second openings. The method can include etching the third dielectric layer to expose portions of each sidewall of the first active structure and the second active structure. The method can include forming a metal layer to at least partially cover the sidewall of the first active structure and the second active structure, where the metal layer is coupled to end portions of each channel layer. The method can include selectively removing the first sacrificial layers to form third openings. The method can include forming a gate structure in the third openings, the gate structure including a ferroelectric layer.

Three-dimensional integration, e.g., the vertical stacking of multiple devices or channels thereof, aims to overcome scaling limitations experienced in planar devices by increasing transistor density in volume rather than area. Although device stacking has been successfully demonstrated and implemented, various embodiments can include numerous operations, and may include minimum feature distances which limit device density and performance. Improved systems and methods to design devices having improved density, performance, or manufacturability is being pursued. Techniques herein include methods of forming vertical transistors or transistors having vertically stacked channels regions, source regions, or drain regions. Techniques herein enable a memory or logic device to be formed from vertically stacked nanosheets or other layers.

These and other aspects and implementations are discussed in detail below. The foregoing information and the following detailed description include illustrative examples of various aspects and implementations and provide an overview or framework for understanding the nature and character of the claimed aspects and implementations. The drawings provide illustrations and a further understanding of the various aspects and implementations and are incorporated in and constitute a part of this specification. Aspects can be combined, and it will be readily appreciated that features described in the context of one aspect of the invention can be combined with other aspects. Aspects can be implemented in any convenient form. As used in the specification and in the claims, the singular form of “a,” “an,” and “the” include plural referents unless the context clearly dictates otherwise. References to “or” may be construed as inclusive so that any terms described using “or” may indicate any of a single, more than one, and all of the described terms.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIGS. 1A, 1B, and 1C collectively illustrate a flowchart of a method for making a semiconductor device, in accordance with some embodiments.

FIGS. 2A, 3A, 4A, 5A, 6A, 7A, 8A, 9A, 10A, 12A, 13A, 15A, 16A, 17A, 18A, and 19 each illustrate a planar top view of a semiconductor device during various fabrication stages, made by the method of FIGS. 1A-1C, in accordance with some embodiments.

FIGS. 2B, 3B, 4B, 5B, 6B, 7B, 8B, 8D, 9B, 10B, 12B, 13B, 15B, 16B, 17B, and 18B each illustrate a cross sectional view of a semiconductor device along line BB′ of FIGS. 2A, 3A, 4A, 5A, 6A, 7A, 8A, 9A, 10A, 12A, 13A, 15A, 16A, 17A, and 18A, respectively, during various fabrication stages, made by the method of FIGS. 1A-1C, in accordance with some embodiments.

FIGS. 2C, 3C, 4C, 5C, 6C, 7C, 8C, 9C, 10C, 12C, 13C, 15C, 16C, and 17C each illustrate a cross sectional view of a semiconductor device along line AA′ of FIGS. 2A, 3A, 4A, 5A, 6A, 7A, 8A, 9A, 10A, 12A, 13A, 15A, 16A, and 17A, respectively, during various fabrication stages, made by the method of FIGS. 1A-1C, in accordance with some embodiments.

FIGS. 11 and 14 each illustrate a 3D perspective view of a semiconductor device, or a portion thereof, as shown in FIGS. 10A and 13A, respectively, during various fabrication stages, made by the method of FIGS. 1A-1C, in accordance with some embodiments.

### DETAILED DESCRIPTION

Reference will now be made to the illustrative embodiments depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

Disclosed herein are embodiments related to devices having stacks of semiconductor channels formed from nanosheets and an isolation structure extending vertically through each stack to form transistors each with a forksheet structure. The stacks can include semiconductor channels including silicon. In some embodiments, silicon germanium sacrificial layers are disposed between the semiconductor channel layers. Based on a scalable architecture of such semiconductor channels, advantageously, the forksheet transistors, as disclosed herein, may be scaled in performance or quantity.

In some aspects, the forksheet transistor provided herein can include a gate structure having a ferroelectric layer disposed between a gate dielectric and a gate electrode, resulting in a non-volatile memory device. Such a forksheet transistor can be configured to include a stack of doped silicon channel layers (e.g., in a silicon junction forksheet transistor) or conductive oxide channel layers. In addition, methods of forming the forksheet transistors provided herein afford various options of epitaxially growing and doping the silicon channel layers.

In some aspects, any number of the forksheet transistors provided herein can be laterally (e.g., side-by-side) arranged with one another or vertically stacked on top of one another, thereby forming an array of forksheet transistors with improved performance in an area-efficient manner. In one such example, the array can include pairs of forksheet transistors having a reduced spacing (i.e., separation distance) therebetween compared to at least some other transistor-to-transistor spacings. In another such example, the array can provide multiple forksheet transistors stacked vertically, allowing more efficient coupling of electrodes (e.g., source/drain contacts) to the forksheet transistors in the array.

In some aspects, forksheet transistors without the ferroelectric layer can be configured as logic devices and can be laterally or vertically integrated with other forksheet transistor-based memory devices to achieve compact and stackable designs for high-density memory applications. In one such example, forksheet transistor-based memory devices including conducive oxide channel layers can be vertically stacked over forksheet transistor-based logic devices. In another such example, forksheet transistor-based logic devices can be laterally disposed adjacent forksheet transistor-based memory devices.

Reference will now be made to the figures, which for the convenience of visualizing the 3D fabrication techniques described herein, illustrate a substrate undergoing a process flow. Unless expressly indicated otherwise, each figure represents one (or a set) of fabrication steps in a process flow for manufacturing the devices described herein. In the figures, connections between conductive layers or materials may be shown. However, it should be understood that these connections between various layers and masks are merely illustrative and are intended to show a capability for providing such connections and should not be considered limiting to the scope of the claims.

Likewise, although the figures and aspects of the disclosure may show or describe devices herein as having a particular shape, it should be understood that such shapes are merely illustrative and should not be considered limiting to the scope of the techniques described herein. For example, although certain figures show various layers defining transistor structures or other electric structures in a rectangular configuration, other shapes are also contemplated, and indeed the techniques described herein may be implemented in any shape or geometry.

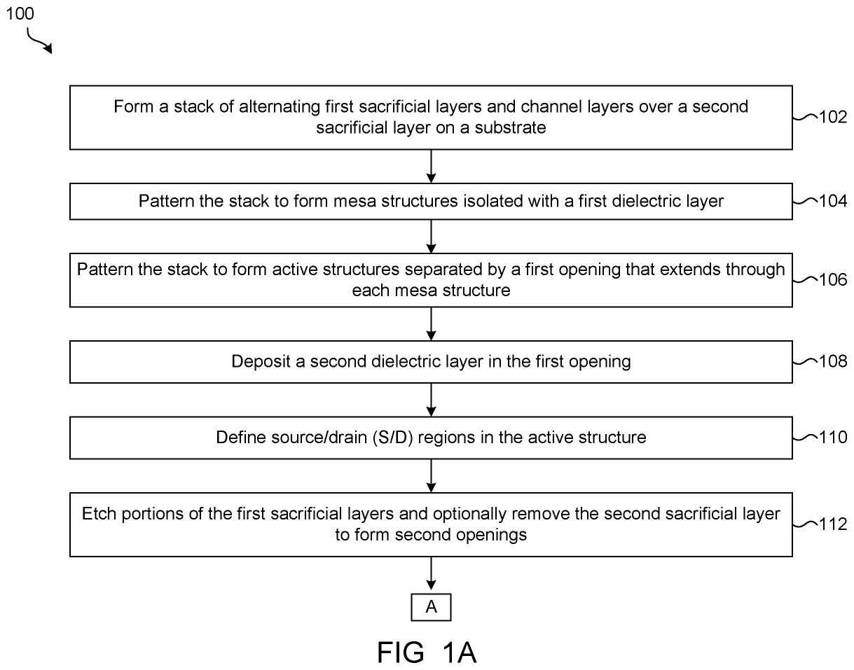

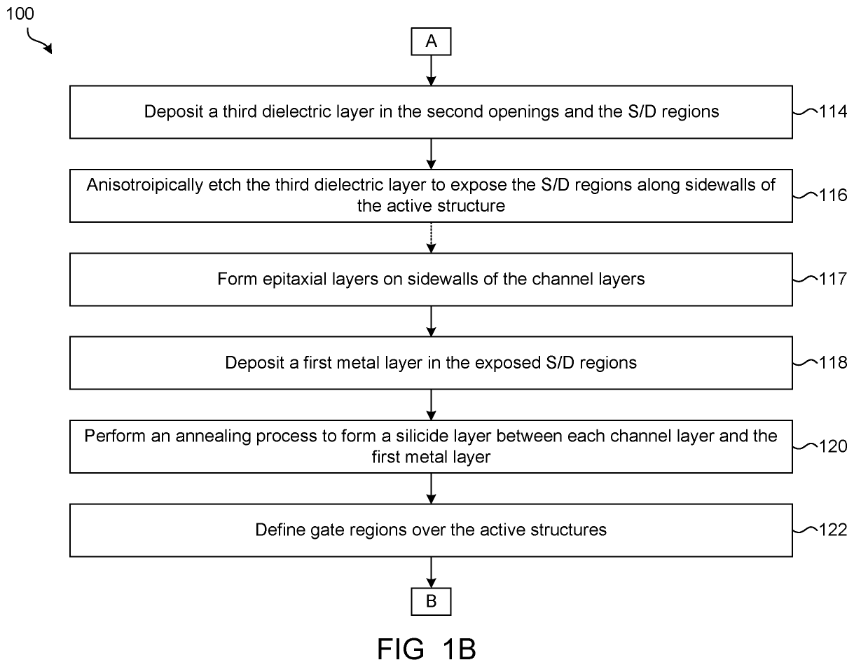

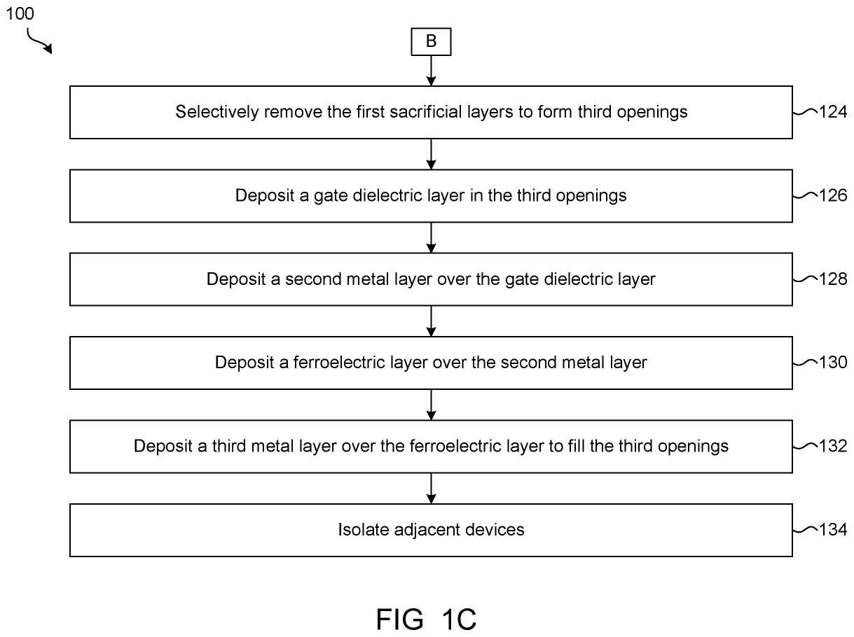

FIGS. 1A-1C collectively illustrate a flowchart of a method 100 for making a semiconductor structure (e.g., a transistor), based on a vertical stack structure. For example, the vertical stack structure can be formed by a plurality of nanosheets to form a semiconductor device. It is noted that the method 100 is merely an example and is not intended to limit the present disclosure. Accordingly, it is understood that additional operations may be provided before, during, and after the method 100 of FIGS. 1A-1C, and that some other operations may only be briefly described herein.

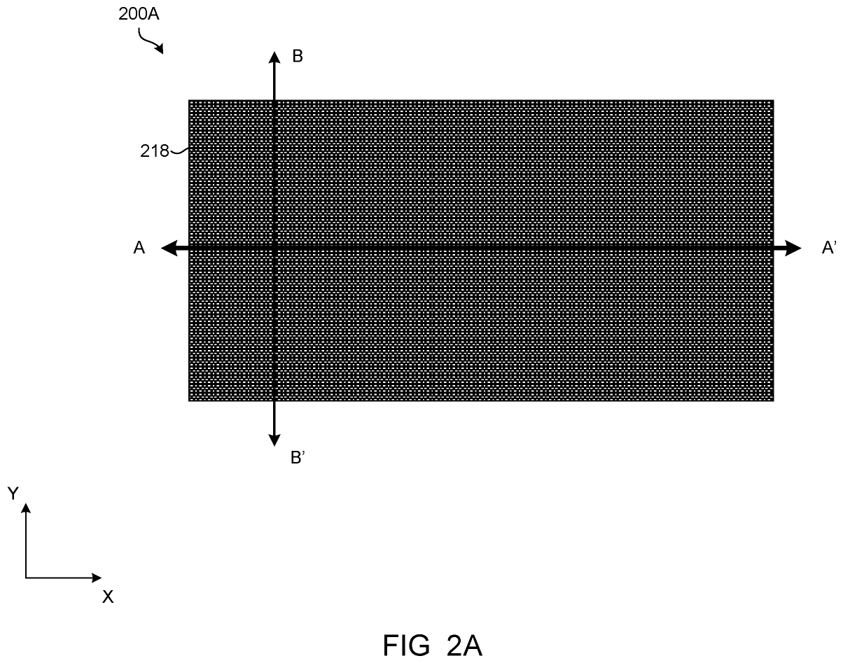

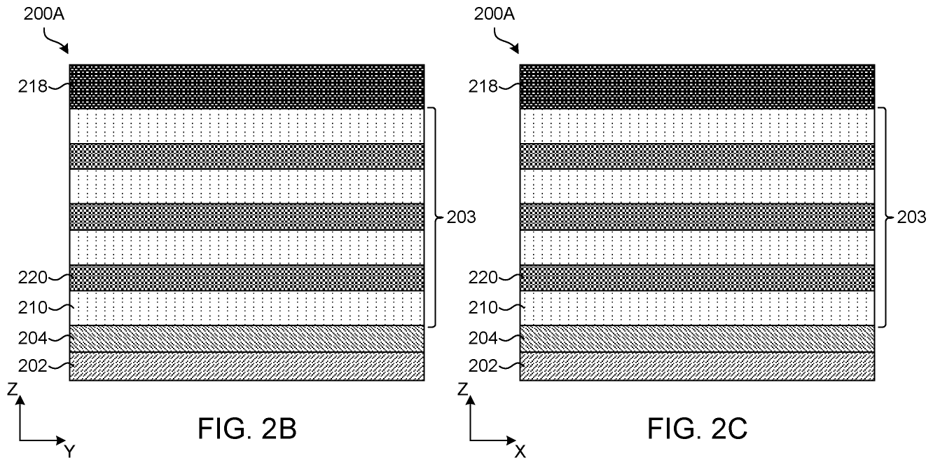

In various embodiments, operations of the method 100 may be associated with top views and cross-sectional views of an example semiconductor structure (also referred to herein as a semiconductor device) 200A at various fabrication stages as shown in FIGS. 2-17C, which will be discussed in further detail below. It should be understood that the semiconductor structure 200A, shown in FIGS. 2A-17C, may include a number of other devices such as inductors, fuses, capacitors, coils, etc., while remaining within the scope of the present disclosure.

Referring to FIGS. 1A and 2A-2C, the method 100 at operation 102 forms a stack 203 protruding from a semiconductor substrate 202. In the present embodiments, the stack 203 includes a number of first sacrificial layers 210 and channel layers 220 over a second sacrificial layer 204, where the first sacrificial layers 210 and the channel layers 220 are interleaved to form the stack 203.

The semiconductor substrate 202 includes a semiconductor material substrate, for example, silicon. Alternatively, the semiconductor substrate 202 may include other elementary semiconductor material such as, for example, germanium. The semiconductor substrate 202 may also include a compound semiconductor such as silicon carbide, gallium arsenic, indium arsenide, and indium phosphide. The semiconductor substrate 202 may include an alloy semiconductor such as silicon germanium, silicon germanium carbide, gallium arsenic phosphide, and gallium indium phosphide. In one embodiment, the semiconductor substrate 202 includes an epitaxial layer. For example, the semiconductor substrate 202 may have an epitaxial layer overlying a bulk semiconductor. Furthermore, the semiconductor substrate 202 may include a semiconductor-on-insulator (SOI) structure. For example, the semiconductor substrate 202 may include a buried oxide (BOX) layer formed by a process such as separation by implanted oxygen (SIMOX) or other suitable technique, such as wafer bonding and grinding.

The first sacrificial layers 210 and the channel layers 220 are alternately disposed on top of one another (e.g., along the Z direction) to form the stack 203. For example, one of the channel layers 220 is disposed over one of the first sacrificial layers 210 then another one of the first sacrificial layers 210 is disposed over the second semiconductor layer 220, so on and so forth. The stack 203 may include any number of alternately disposed first sacrificial layers 210 and channel layers 220. The first sacrificial layers 210 and the channel layers 220 may be formed to different thicknesses. The first sacrificial layers 210 may have different thicknesses from one layer to another layer. The channel layers 220 may have different thicknesses from one layer to another layer. The thickness of each of the first sacrificial layers 210 and the channel layers 220 may range from a few nanometers to a few tens of nanometers. In the present embodiments, the stack 203 includes four of the first sacrificial layers 210 and three of the channel layers 220.

In the present embodiments, the first sacrificial layers 210 and the channel layers 220 have different compositions. In some embodiments, the first sacrificial layers 210 and the channel layers 220 have compositions that provide different oxidation rates and/or different etching selectivity between the layers. In some embodiments, the first sacrificial layer 210 includes a first semiconductor material, such as silicon germanium (Si₁₋ₓGeₓ), and the channel layer 220 includes a second semiconductor material different from the first semiconductor material, such as silicon (Si).

In some embodiments, the channel layer 220 includes silicon that is undoped (i.e., intrinsic) or substantially dopant-free (e.g., having an extrinsic dopant concentration from about 0 cm⁻³ to about 1×10¹⁷ cm⁻³), where, for example, no intentional doping is performed when forming the channel layers 220. In some embodiments, the channel layer 220 includes doped silicon having an n-type dopant configured to provide an n-type device (e.g., an n-type transistor) or a p-type dopant configured to provide a p-type device (e.g., a p-type transistor). The n-type dopant may include phosphorous and arsenic, for example, and the p-type dopant may include boron or gallium, for example. Unless otherwise noted, subsequent operations of the method 100 are described in reference to the first sacrificial layer 210 including silicon germanium and the channel layer 220 including silicon doped with an n-type dopant for purposes of illustration.

In some embodiments, the first sacrificial layer 210 includes a semiconductor material, such as silicon germanium, and the channel layer 220 includes a conductive oxide. Examples of the conductive oxides include indium gallium zinc oxide (IGZO), indium tin oxide (ITO), indium zinc oxide (IZO), indium tungsten oxide (IWO), zinc oxide (ZnO), indium oxide (In₂O₃), tin oxide (SnO₂), the like, or combinations thereof.

The second sacrificial layer 204 is formed between the semiconductor substrate 202 and the stack 203 (i.e., a bottommost first sacrificial layer 210 of the stack 203). The second sacrificial layer 204 includes a semiconductor material different from both the first sacrificial layers 210 to provide etching selectivity with respect to both the first sacrificial layers 210 and the channel layers 220 and is configured to be replaced, at least partially replaced, with a dielectric layer (e.g., a dielectric layer 256) in subsequent operations. In some embodiments, the second sacrificial layer 204 includes silicon germanium (Si_{1-y}Ge_{y}), where y is different from x such that the first sacrificial layer 210 and the second sacrificial layer 204 differ in composition. For example, x may be about 35% and y may be about 65%. In this regard, the first sacrificial layer 210 and the second sacrificial layer 204 also exhibit etching selectivity with respect to one another.

One or both of the first sacrificial layers 210 and the channel layers 220 may include other materials, for example, a compound semiconductor such as silicon carbide, gallium arsenide, gallium phosphide, indium phosphide, indium arsenide, and/or indium antimonide, an alloy semiconductor such as GaAsP, AlInAs, AlGaAs, InGaAs, GaInP, and/or GaInAsP, or combinations thereof. The materials of the first sacrificial layers 210 and the channel layers 220 may be chosen based on their relative oxidation rates and/or etching selectivity.

The method 100 at operation 102 may form the second sacrificial layer 204 and the stack 203 by one or more epitaxial growth processes from the semiconductor substrate 202. For example, each of the second sacrificial layer 204, the first sacrificial layers 210, and the channel layers 220 may be grown by a molecular beam epitaxy (MBE) process, a chemical vapor deposition (CVD) process such as a metal organic CVD (MOCVD) process, the like, or combinations thereof. During the epitaxial growth process, the crystal structure of the semiconductor substrate 202 extends upwardly, resulting in the second sacrificial layer 204, the first sacrificial layers 210, and the channel layers 220 having the same, or substantially the same, crystal orientation with the semiconductor substrate 202.

Subsequently, the method 100 at operation 102 forms a first mask layer 218 over the stack 203 to protect the underlying layers from being damaged during subsequent operations. In some embodiments, the first mask layer 218 includes multiple sublayers (not depicted separately). For example, the first mask layer 218 may include silicon oxide, silicon nitride, silicon oxynitride, silicon carbonitride, the like, or combinations thereof. The various sublayers of the first mask layer 218 may each be formed using any suitable method including CVD, atomic layer deposition (ALD), low-pressure chemical vapor deposition (LPCVD), plasma enhanced chemical vapor deposition (PECVD), chemical oxidation, thermal oxidation, the like, or combinations thereof.

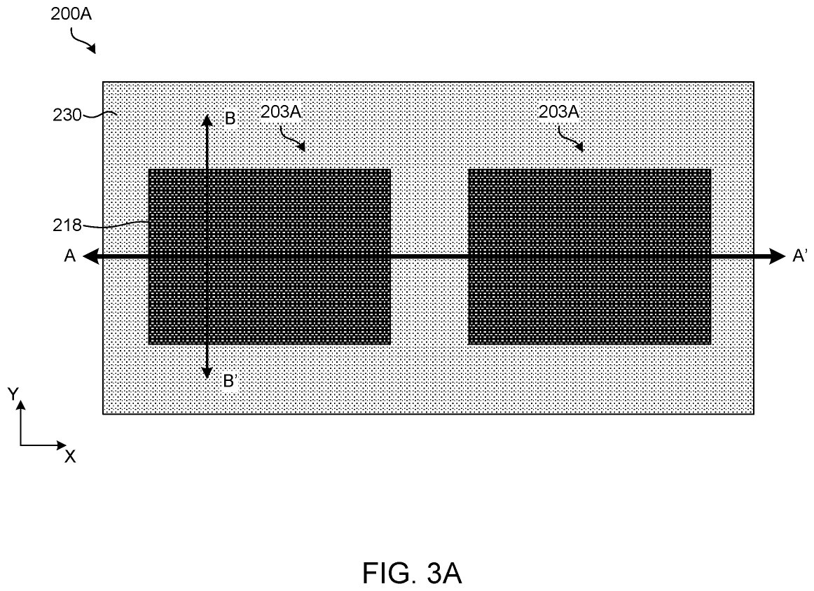

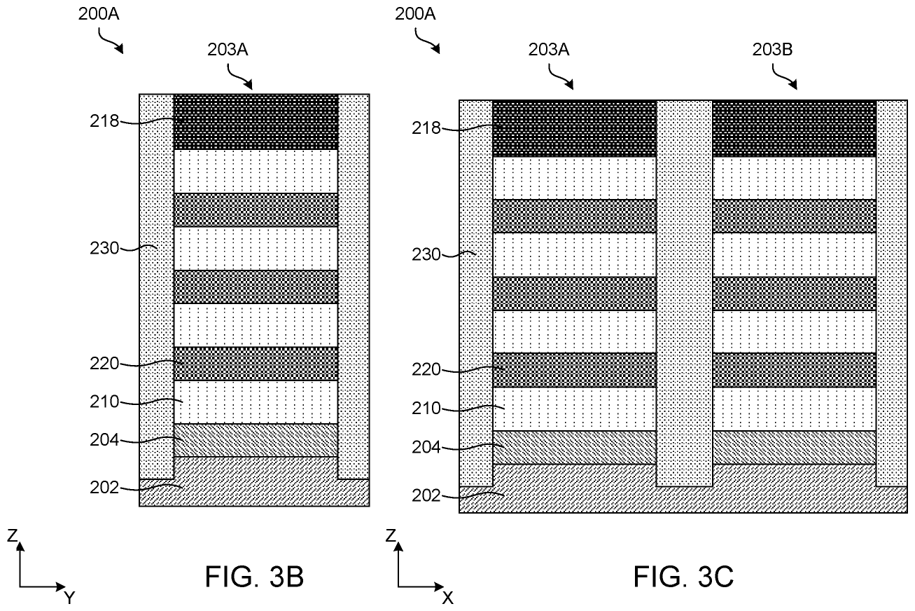

Referring to FIGS. 1A and 3A-3B, the method 100 at operation 104 defines and isolate two mesa structures 203A and 203B in the stack 203.

In the present embodiments, the mesa structures 203A and 203B are formed by patterning the stack 203 using, for example, photolithography and etching techniques. For example, the first mask layer 218 may be first patterned using photolithography techniques. Generally, photolithography techniques utilize a photoresist layer (not shown) that is deposited, irradiated (or exposed), and developed to remove portions of the photoresist layer. The remaining photoresist layer protects the underlying material, such as the first mask layer 218 in this example, from subsequent processing steps, such as etching. Thereafter, the patterned photoresist layer is used to etch the first mask layer 218 and form a patterned first mask layer 218. The patterned first mask layer 218 is then used as an etch mask to etch the stack 203 and form the mesa structures 203A and 203B separated by an opening (not depicted). Etching the stack 203 may be implemented by any suitable etching process, such as a dry etching process, a wet etching process, a reactive ion etching (RIE) process, the like, or combinations thereof. After etching the stack 203, the patterned photoresist layer is removed from the first mask layer 218 by a suitable process, such as resist stripping or plasma ashing.

Subsequently, a first dielectric layer 230 is deposited to encapsulate the semiconductor structure 200A and fill the opening, thereby isolating the mesa structures 203A and 203B. The first dielectric layer 230 may include an oxide, a nitride, a low-k dielectric material (e.g., having a dielectric constant of less than that of silicon oxide, which is about 3.9), the like, or combinations thereof. Examples of the first dielectric layer 230 may include silicon oxide, phosphosilicate glass (PSG), borosilicate glass (BSG), boron-doped phosphosilicate glass (BPSG), undoped silicate glass (USG), the like, or combinations thereof. The first dielectric layer 230 may be formed by a process such as CVD, high density plasma CVD (HDP-CVD), flowable CVD (FCVD) (e.g., including a CVD-based deposition process implemented in a remote plasma system and a curing process to convert the deposited material to another material, such as an oxide), the like, or combinations thereof. Other dielectric materials and/or other formation processes may be used. In an example, the first dielectric layer 230 includes silicon oxide and is formed by a FCVD process. An anneal process may be performed once the first dielectric layer 230 is deposited.

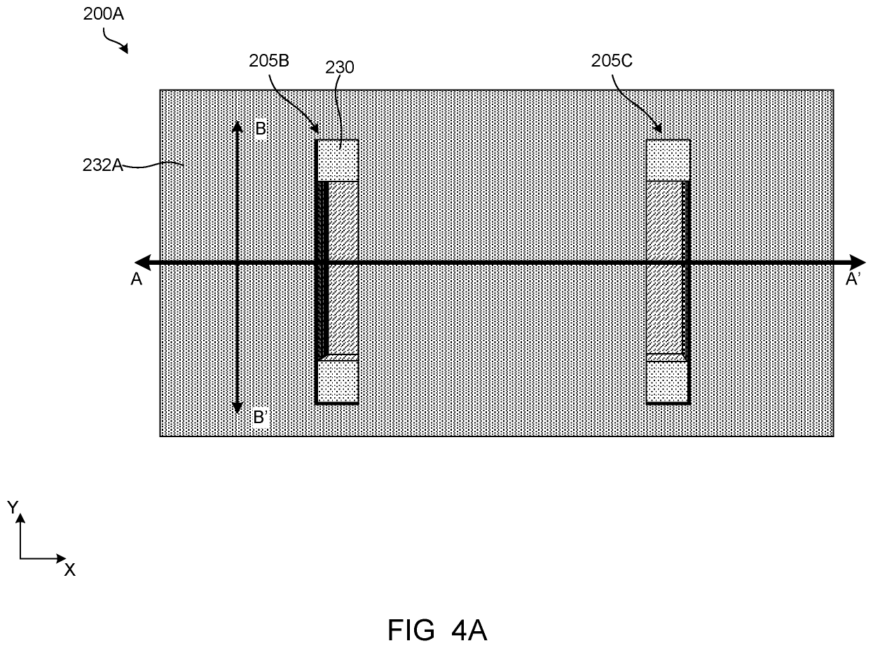

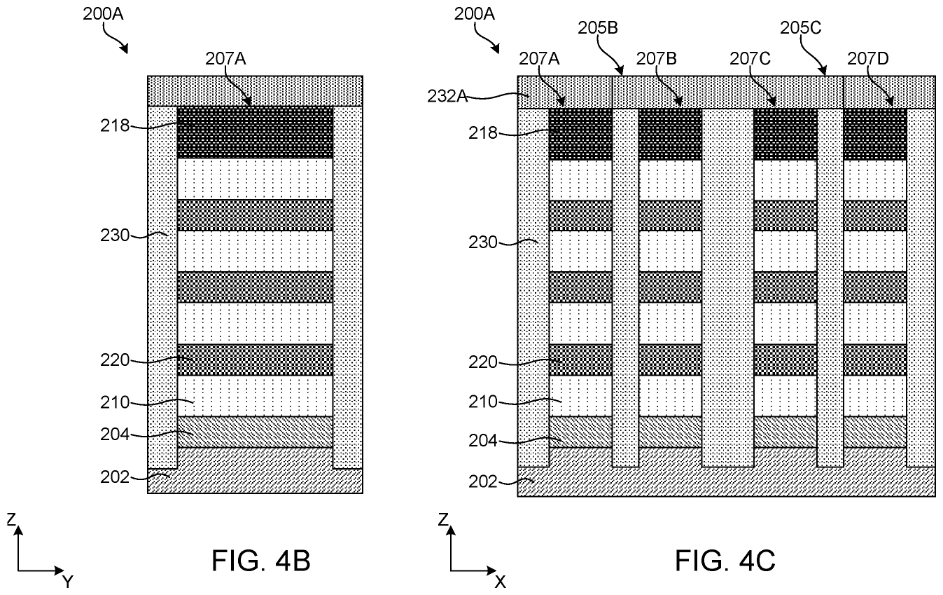

Referring to FIGS. 1A and 4A-4C, the method 100 at operation 106 patterns each of the mesa structures 203A and 203B to form pairs of active structures within each mesa structure. In the present embodiments, the mesa structure 203A is patterned to form active structures 207A and 207B, and the mesa structure 203B is patterned to form active structures 207C and 207D.

The mesa structures 203A and 203B may be patterned using the photolithography and etching techniques similar to the patterning of the stack 203. For example, a photoresist layer (not depicted) is deposited over portions of the mesa structures 203A and 203B, irradiated, and developed to form a patterned photoresist layer 232A. Thereafter, the patterned photoresist layer 232A is used to pattern the first mask layer 218 to form a patterned first mask layer 218, which is then used as an etch mask to etch the mesa structures 203A and 203B, resulting in an opening 205B between the active structures 207A and 207B and an opening 205C between the active structures 207C and 207D. In some embodiments, as depicted in FIG. 4C, each of the mesa structures 203A and 203b are over-etched such that openings 205B and 205C extend through the second sacrificial layer 204 and partially penetrate the substrate 202. Such over-etching ensures that the adjacent active structures are completely isolated from one another. The patterned photoresist layer 232A is subsequently removed by a suitable method described above.

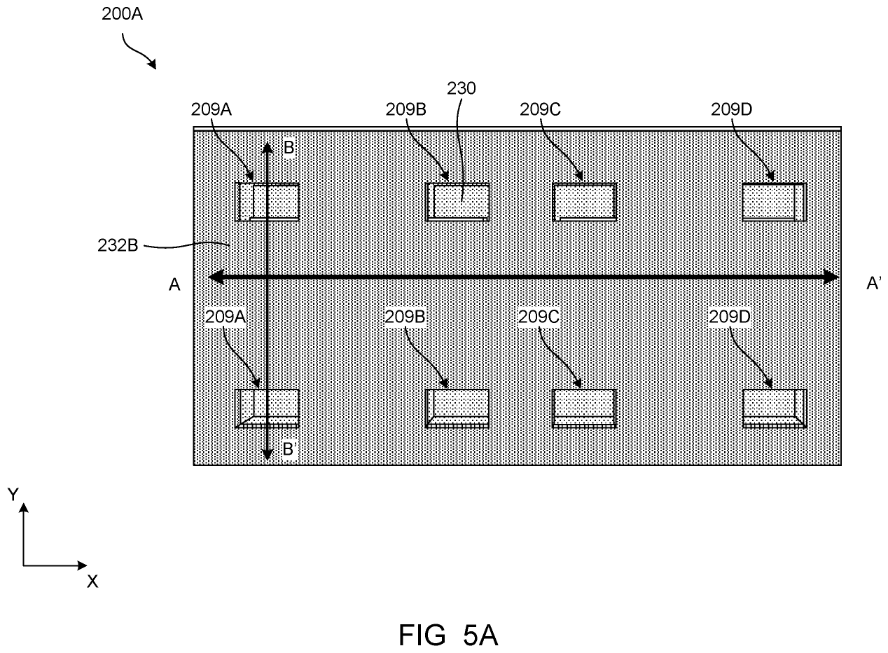

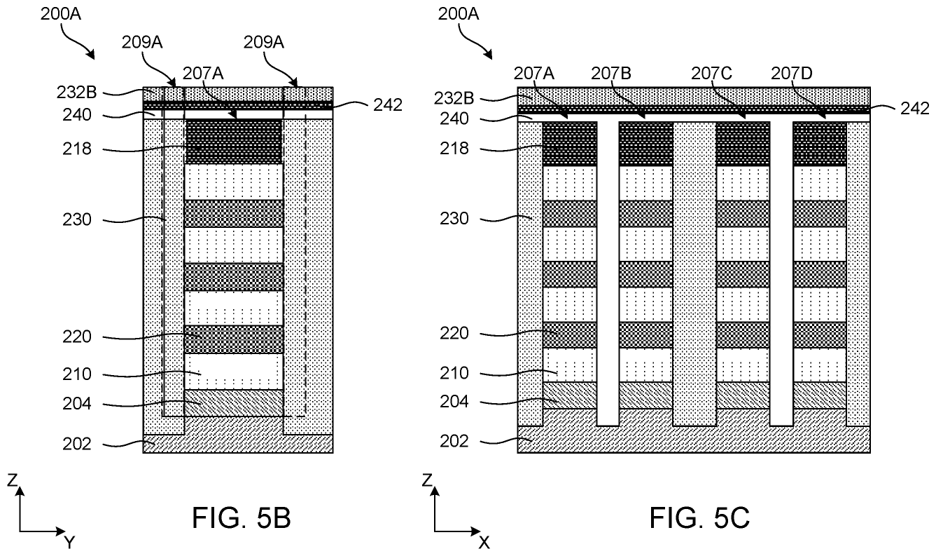

Referring to FIGS. 5A-5C, the method 100 at operation 108 deposits a second dielectric layer (or isolation structure) 240 to fill the openings 205B and 205C and deposits a second mask layer 242 over the second dielectric layer 240.

In the present embodiments, the second dielectric layer 240 differs from the first dielectric layer 230 in composition to provide etching selectivity therebetween. The second dielectric layer 240 may include an oxide, a nitride, a low-k dielectric material, the like, or combinations thereof. The second dielectric layer 240 may be formed by a process similar to that of forming the first dielectric layer 230, such as by CVD, HDP-CVD, FCVD, the like, or combinations thereof. In some embodiments, portions of the second dielectric layer 240 are formed over top surfaces of the active structures 207A-207D. In some embodiments, such portions are removed by a chemical-mechanical polishing/planarization (CMP) process, thereby exposing the top surfaces of the active structures 207A-207D.

Subsequently, the method 100 at operation 108 deposits the second mask layer 242 to overlay the top surfaces of the active structures 207A-207D. The second mask layer 242 may have the same composition as the first mask layer 218 and may be formed by the same process, such as by CVD, ALD, the like, or combinations thereof.

Still referring to FIGS. 1A and 5A-5C, the method 100 at operation 110 patterns the active structures 207A-207D to define source/drain (S/D) regions (or recesses) 209A-209D, respectively.

In the present embodiments, the active structures 207A-207D are patterned using the photolithography and etching techniques similar to the patterning of the stack 203. For example, a photoresist layer (not depicted) is deposited over portions of the second mask layer 242, irradiated, and developed to form a patterned photoresist layer 232B. The second mask layer 242 is then etched using the patterned photoresist layer 232B, resulting in a patterned second mask layer 242, which is then used as an etch mask to etch the active structures 207A-207D and define the S/D regions 209A-209D, respectively. The patterned photoresist layer 232B is subsequently removed by a suitable method described above. As shown in FIG. 5B, the S/D regions 209A are defined along opposing sidewalls of the active structure 207A, where the opposing sidewalls are separated along the Y direction.

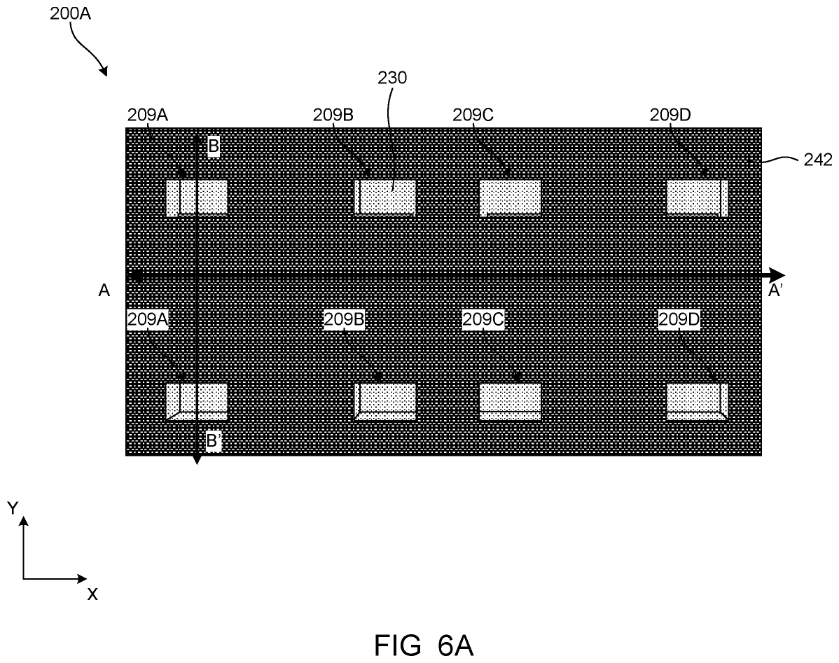

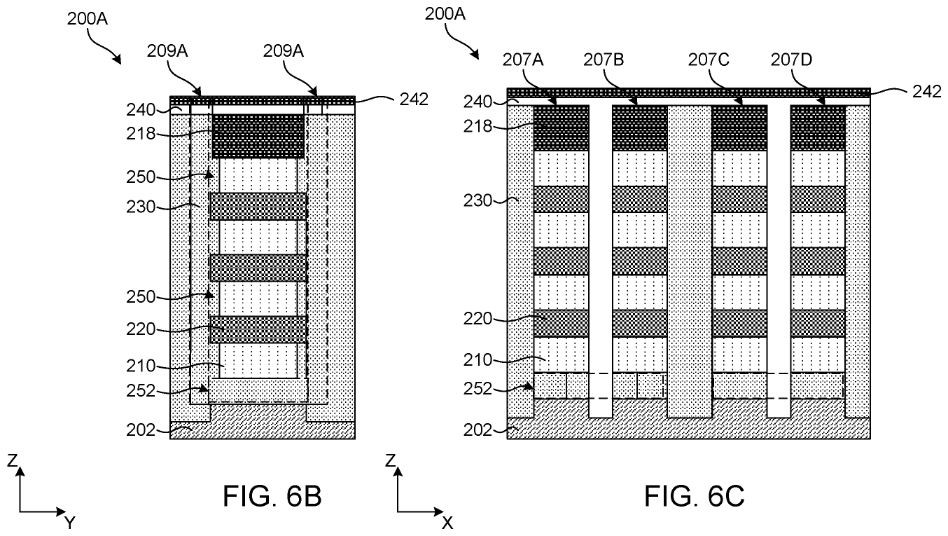

Referring to FIGS. 1A and 6A-6C, the method 100 at operation 112 etches portions (e.g., end portions) of each first sacrificial layer 210 to form openings (or recesses) 250.

In the present embodiments, the method 100 performs a selective etching process to entirely remove the second sacrificial layer 204 and partially remove the first sacrificial layers 210 without removing, or substantially removing, portions of the channel layers 220. In this regard, the selective etching process may be implemented using a suitable etchant that substantially reacts or interacts with both the first sacrificial layer 204 and the second sacrificial layers 210 (e.g., including silicon germanium, albeit with different Ge compositions) but not with the channel layers 220 (e.g., including silicon or a conductive oxide). In some embodiments, the selective etching process includes a dry etching process, a wet etching process, an RIE process, the like, or combinations thereof. In some embodiments, a duration of the selective etching process is adjusted to control a width of the opening 250 along the Y direction.

In some embodiments, as depicted in FIGS. 6B and 6C, the selectively etching process at operation 112 removes the second sacrificial layer 204 to form an opening 252. In contrast to the partial removal of the first sacrificial layers 210, the second sacrificial layer 204 is entirely removed from the semiconductor structure 200A such that the opening 252 is interposed between the bottommost first sacrificial layer 210 of the stack 203 and the substrate 202.

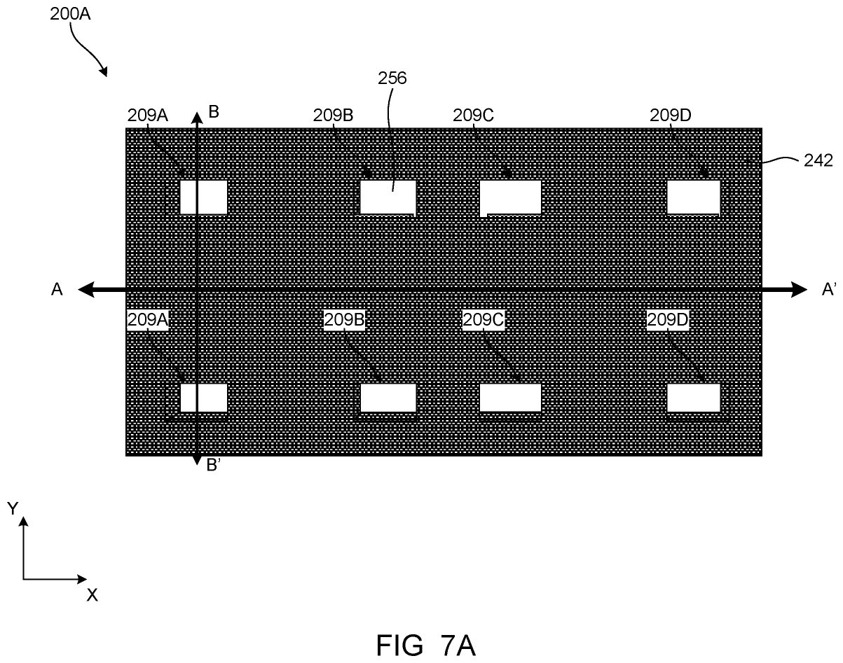

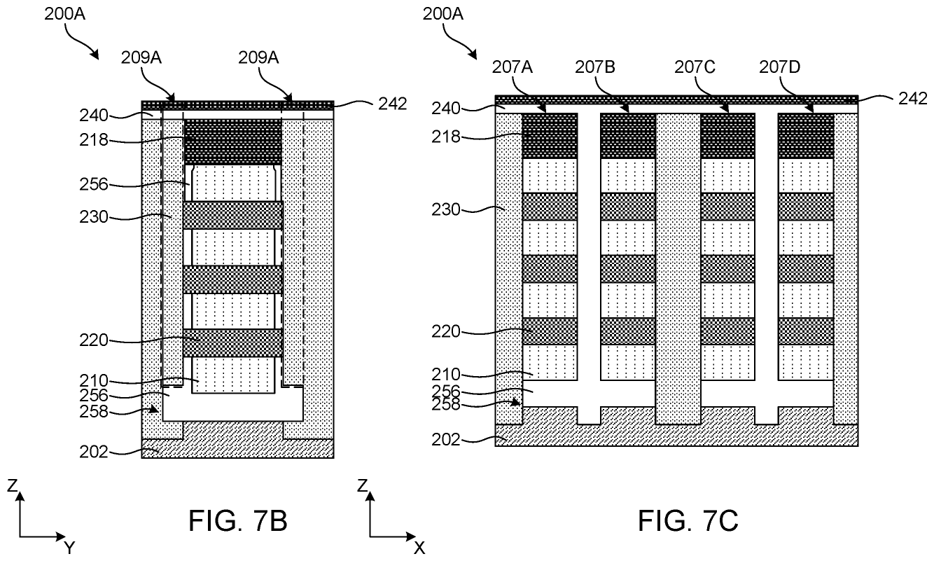

Referring to FIGS. 1B and 7A-7C, the method 100 at operation 114 deposits a third dielectric layer 256 to fill the openings 250, the opening 252, and the S/D regions 209A-209D.

In the present embodiments, the third dielectric layer 256 has a composition that differs from that of the first dielectric layer 230 and may include an oxide, a nitride, a low-k dielectric material, a high-k dielectric material (e.g., having a dielectric constant of greater than that of silicon oxide, which about 3.9), the like, or combinations thereof. In some embodiments, the third dielectric layer 256 has a composition similar to or the same as that of the second dielectric layer 240. The third dielectric layer 256 may be deposited using any suitable process, such as CVD, ALD, physical vapor deposition (PVD), the like, or combinations thereof. As depicted in FIGS. 7B and 7C, top portions of the third dielectric layer 256 are formed in the openings 250 and along the sidewalls of the first sacrificial layer 210, and a bottom portion of the third dielectric layer 256 is formed in the opening 252 to isolate the bottommost first sacrificial layer 210 from the substrate 202. In some embodiments, the bottom portion of the third dielectric layer 256 is alternatively referred to as an isolation structure 258.

Now referring to FIGS. 1B and 7A-7C, the method 100 at operation 116 etches portions of the third dielectric layer 256 to re-expose the S/D regions 209A-209D.

In the present embodiments, the third dielectric layer 256 is etched in an anisotropic manner such that only portions of the third dielectric layer 256 adjacent the sidewalls of the channel layers 220 are etched, while the remaining portions of the third dielectric layer 256 along the sidewalls of the first sacrificial layers 210 are vertically aligned with the sidewalls of the channel layers 220. In this regard, the remaining portions of the third dielectric layer 256 are configured as spacers (e.g., inner spacers) between the subsequently formed gate structure (in place of the first sacrificial layers 210) and the S/D regions 209A-209D and are alternatively referred to as spacers 256. As depicted in FIG. 7B, the partial etching of the third dielectric layer 256 is controlled (e.g., by adjusting the duration of the etching process) to stop on the bottom portion of the third dielectric layer 256 (i.e., the isolation structure 258). The etching process implemented at operation 116 may include a dry etching process, an RIE process, the like, or combinations thereof.

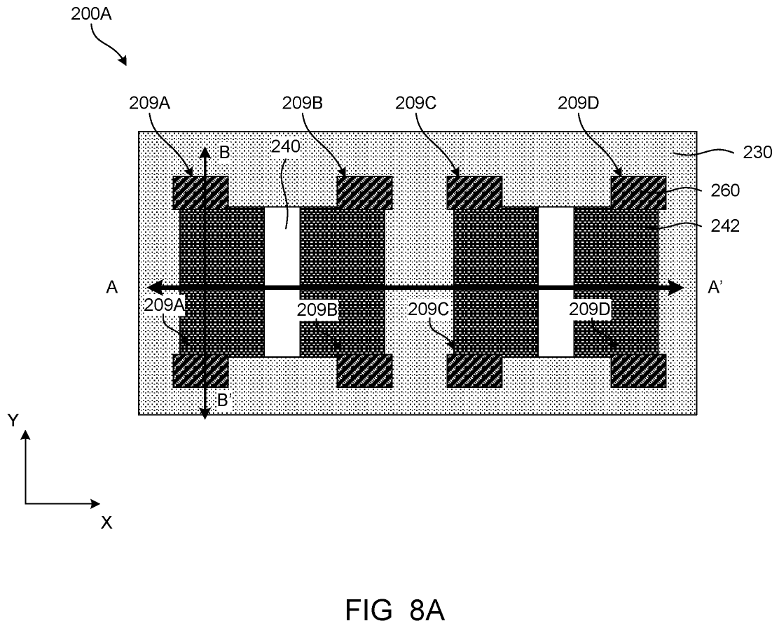

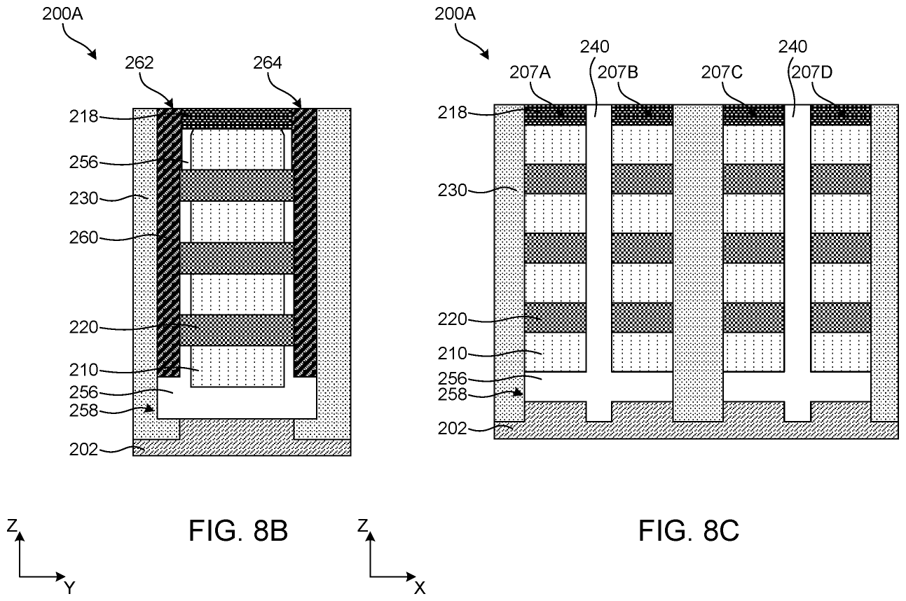

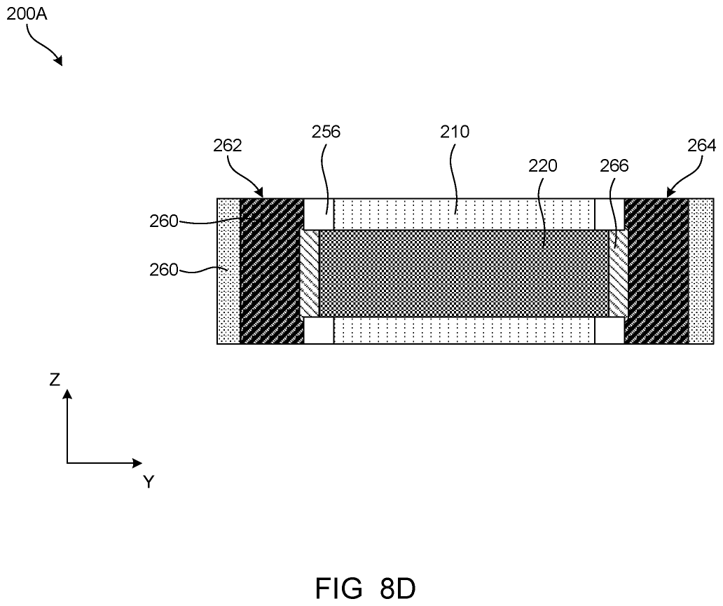

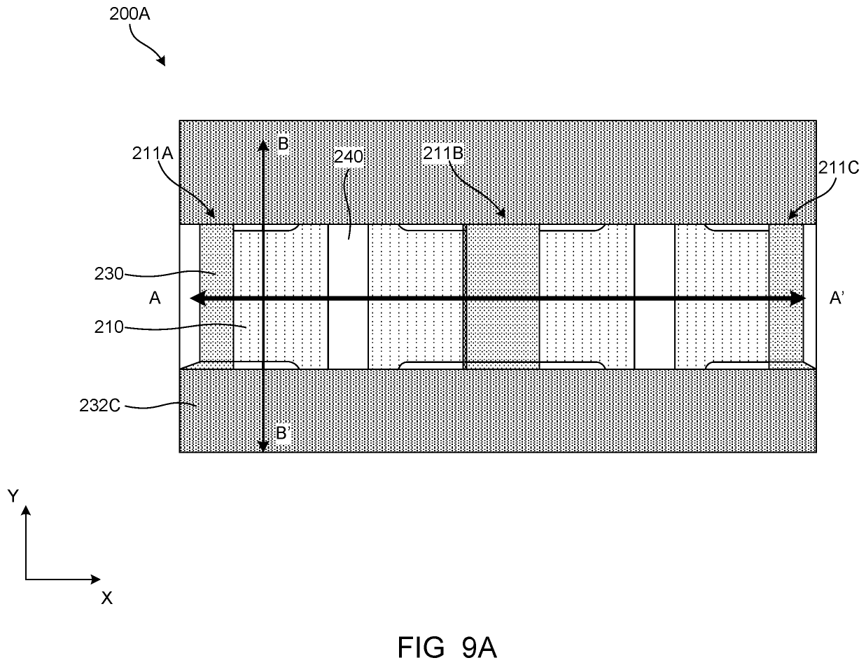

Referring to FIGS. 1B and 8A-8D, the method 100 at operation 118 deposits a first metal layer 260 over the S/D regions 209A-209D, resulting in a first electrode (e.g., a first S/D electrode) 262 and a second electrode (e.g., a second S/D electrode) 264.

The first metal layer 260 may include any suitable conductive material (e.g., a metal), such as tungsten, copper, aluminum, ruthenium, cobalt, silver, gold, the like, or combinations thereof. The first metal layer 260 may be deposited using any suitable process, such as CVD, PVD, ALD, electroplating, electroless plating, the like, or combinations thereof. In some embodiments, a barrier layer and/or a seed layer are formed over the S/D regions 209A-209D before depositing the first metal layer 260.

For embodiments in which the channel layers 220 include a doped semiconductor material, such as doped silicon, or a conductive oxide, the first electrode 262 and the second electrode 264 are each configured as an S/D electrode (e.g., a source electrode and a corresponding drain electrode, respectively). For embodiments in which the channel layers 220 include an intrinsic or un-doped semiconductor material, such as intrinsic silicon, the first electrode 262 and the second electrode 264 are each configured as an S/D contact feature (e.g., a source contact feature and a drain contact feature, respectively).

In some embodiments, referring to FIGS. 1B and 8D, the method 100 at operation 120 performs an annealing process before or after depositing the first metal layer 260, thereby forming a silicide layer 266 between the sidewall of each channel layer 220 and the first metal layer 260. In some embodiments, operation 120 is omitted.

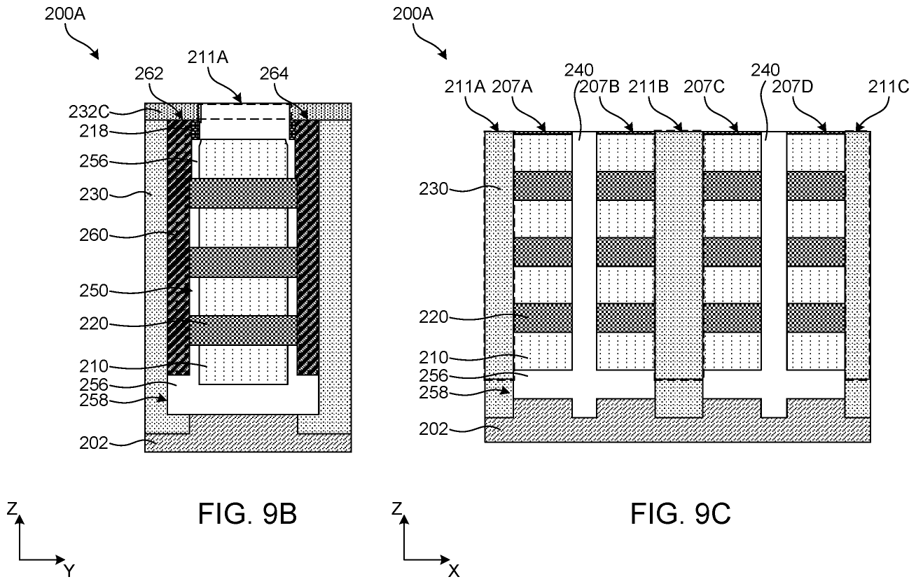

Referring to FIGS. 1B and 9A-9C, the method 100 at operation 122 defines gate regions (or gate trenches or gate recesses) 211A, 211B, and 211C adjacent the active structures 207A, 207B/207C, and 207D, respectively.

In the present embodiments, the method 100 defines the gate regions 211A-211C by first patterning the second mask layer 242. The second mask layer 242 may be patterned using the photolithography and etching techniques similar to the patterning of the stack 203. For example, a photoresist layer (not depicted) is deposited over the semiconductor structure 200A, irradiated, and developed to form a patterned photoresist layer 232C, which exposes portions of the second mask layer 242 over active structures 209A-209D. The second mask layer 242 is then etched using the patterned photoresist layer 232C as an etch mask, resulting in a patterned second mask layer 242. The patterned second mask layer 242 is subsequently used as an etch mask to remove portions of the first dielectric layer 230 along a sidewall of each of the active structures 207A-207D. As depicted in FIGS. 9B and 9C, the method 100 at operation 122 exposes a top surface of a topmost first sacrificial layer 210 and a sidewall of each of the underlying first sacrificial layers 210 in the gate regions 211A-211C. In some embodiments, as depicted in FIG. 9C, the gate region 211B is interposed between the active structures 207B and 207C. The patterned photoresist layer 232C is subsequently removed by a suitable method described above.

Referring to FIGS. 1C, 10A-10C, and 11, the method 100 at operation 124 removes the first sacrificial layers 210 exposed in the gate regions 211A-211C to form openings 269 interposed between two vertically adjacent channel layers 220.

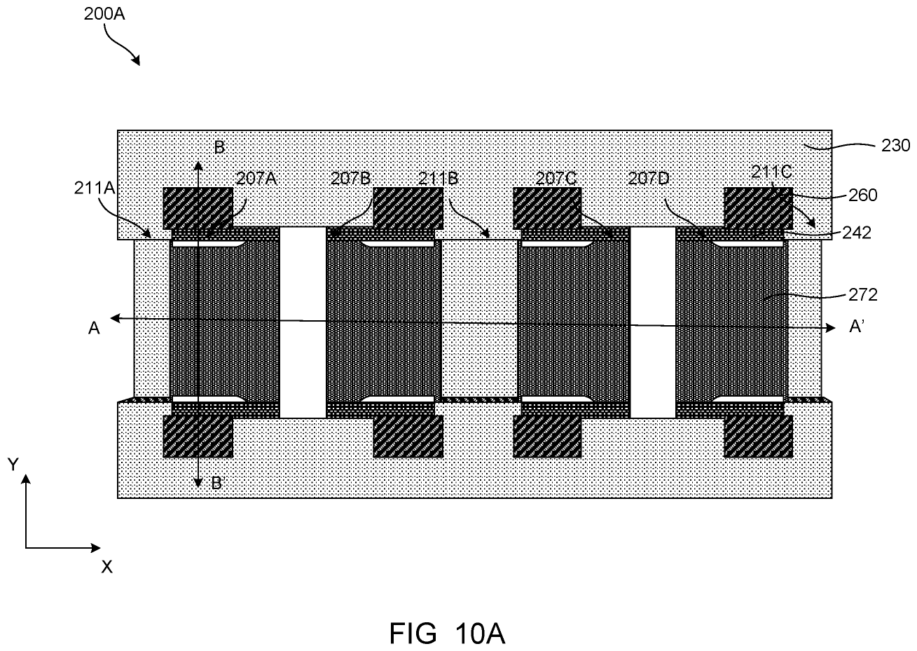

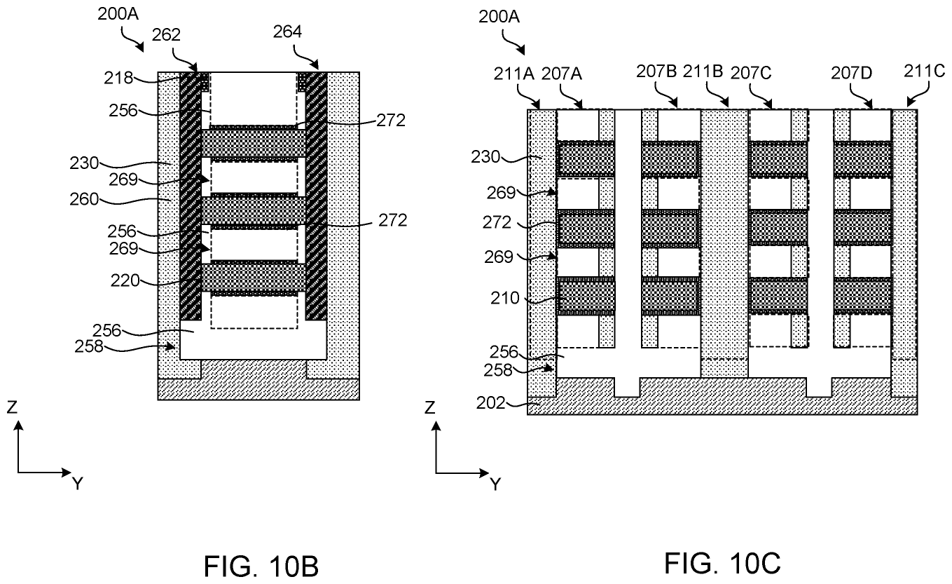

In the present embodiments, the method 100 performs a selective etching process to entirely remove the first sacrificial layers 210 without removing, or substantially removing, portions of the channel layers 220. In this regard, the selective etching process may be implemented using a suitable etchant that substantially reacts or interacts with only the first sacrificial layer 204 but not with the channel layers 220 (e.g., including silicon or a conductive oxide) or the surrounding dielectric layers (e.g., the first dielectric layer 230). In some embodiments, the selective etching process includes a dry etching process, a wet etching process, an RIE process, the like, or combinations thereof. As depicted in FIG. 10B, each opening 269 exposes the remaining portions of the third dielectric layer 256 (i.e., the spacers 256).

In some embodiments, an optional doping (or implantation) process is performed after forming the openings 269 to introduce a dopant of a certain conductivity type to the channel layers 220 exposed in the openings 269. In one such example, where the channel layers 220 include un-doped silicon, the channel layers 220 of the active structure 207A may be doped with an n-type dopant to form a p-type device (e.g., a p-type metal-oxide semiconductor, or PMOS, device) and the channel layers 220 of the active structure 207B may be doped with a p-type dopant to form an n-type device (e.g., an n-type MOS, or NMOS, device).

Still referring to FIGS. 1C, 10A-10C, and 11, the method 100 at operation 126 deposits a gate dielectric layer 272 over the channel layers 220 exposed in each of the openings 269 and the gate regions 211A-211C.

In the present embodiments, the gate dielectric layer 272 includes a suitable dielectric material, such as a high-k dielectric material having a metal oxide or a silicate of hafnium, aluminum, zirconium, lanthanum, magnesium, barium, titanium, lead, the like, or combinations thereof. The gate dielectric layer 272 may include a stack of different dielectric materials. The gate dielectric layer 272 may be deposited using any suitable process, such as ALD, CVD, PECVD, PVD, the like, or combinations thereof. In some embodiments, the gate dielectric layer 272 may optionally include a substantially thin oxide (e.g., silicon oxide) layer.

In some embodiments, the gate dielectric layer 272 is selectively formed on the exposed surfaces of the channel layers 220 but not on, or not substantially on, the third dielectric layer 256. Alternatively, the gate dielectric layer 272 is non-selectively formed on both the exposed surfaces of the channel layers 220 and on the third dielectric layer 256. As depicted in FIG. 10C, the gate dielectric layer 272 wraps around the end portion of each channel layer 220 exposed in the respective gate regions 211A-211C.

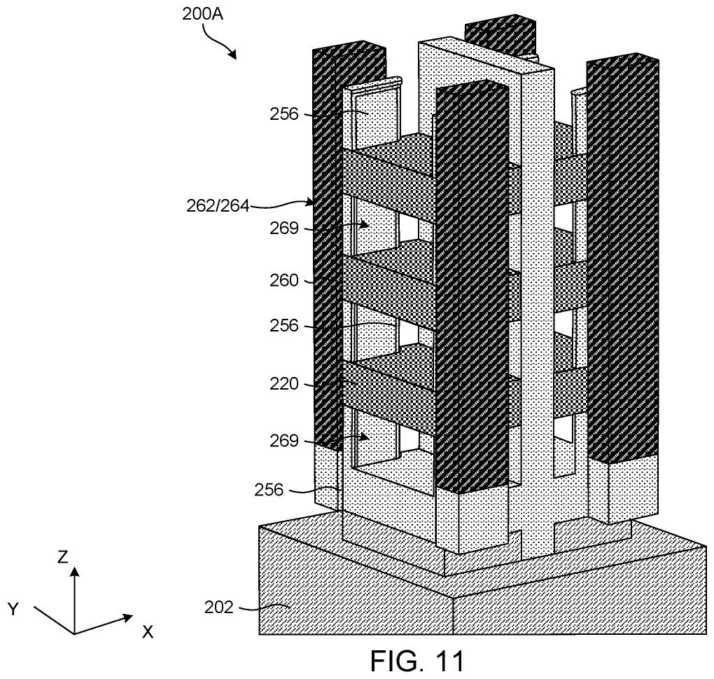

FIG. 11 illustrates a 3D perspective view of the semiconductor structure 200A after performing the operation 126. It is noted that the first dielectric layer 230 and the gate dielectric layer 272 are omitted in FIG. 11 to show portions of the semiconductor structure 200A in detail.

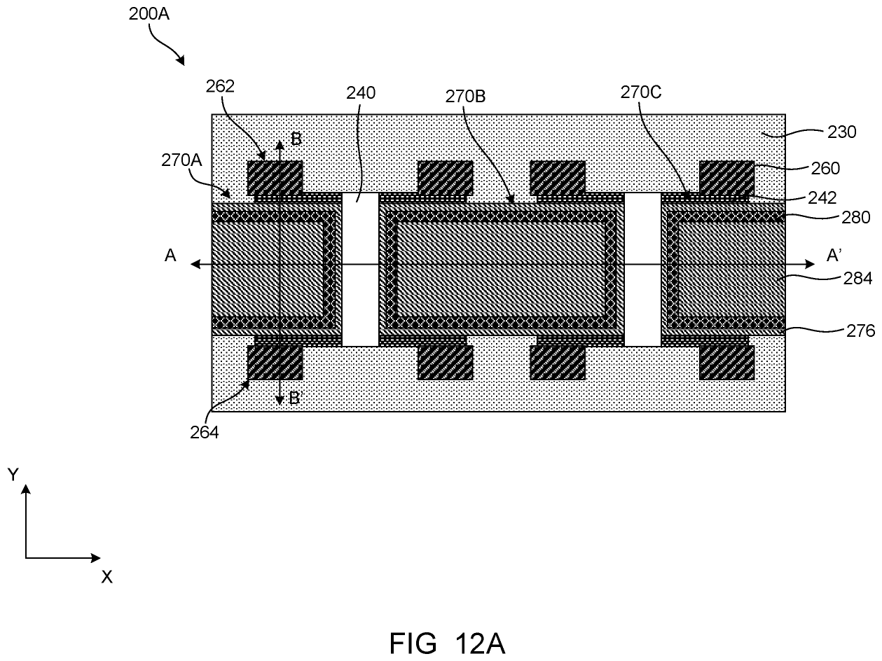

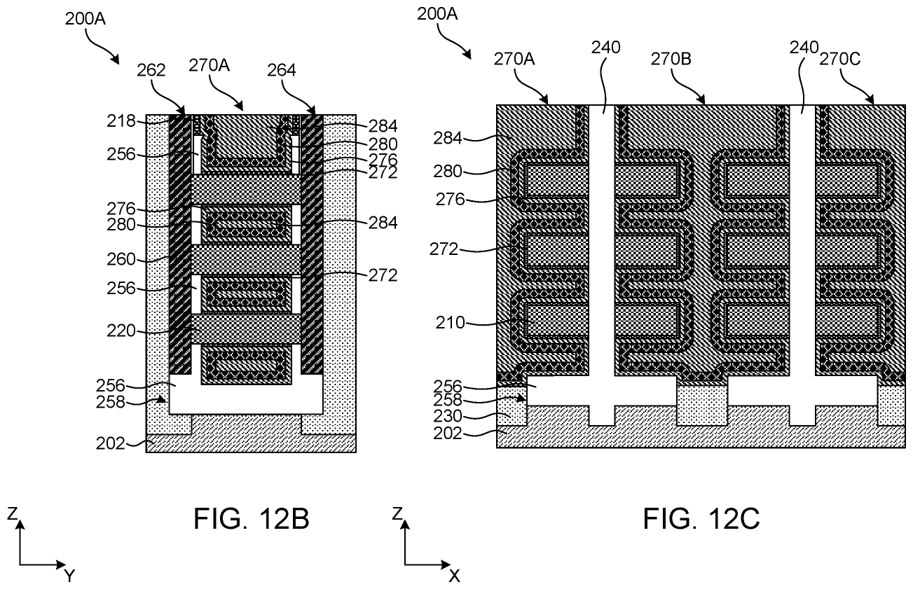

Referring to FIGS. 1C and 12A-12C, the method 100 at operation 128 deposits a second metal layer 276 over the gate dielectric layer 272.

In some embodiments, the second metal layer 276 includes a work function metal, such as a p-type work function metal, an n-type work function metal, or combinations thereof. The work function metal may also be referred to as a work function layer. Example work function metals include ruthenium, molybdenum, aluminum, titanium, silver, manganese, zirconium, TiN, TaN, WN, ZrSi₂, MoSi₂, TaSi₂, NiSi₂, TaAl, TaAlC, TiAlN, TaC, TaCN, TaSiN, the like, or combinations thereof. The second metal layer 276 may be deposited by CVD, PVD, ALD, electroplating, electroless plating, or combinations thereof, and subsequently planarized using one or more CMP processes. In the present embodiments, the second metal layer 276 is non-selectively formed on the gate dielectric layer 272 and the adjacent dielectric layers (e.g., the second dielectric layer 240 and the third dielectric layer 256) in the openings 269 and the gate regions 211A-211C.

Referring to FIGS. 1C and 12A-12C, the method 100 at operation 130 deposits a ferroelectric layer 280 over the second metal layer 276.

In the present embodiments, the ferroelectric layer 280 includes hafnium oxide (e.g., hafnium oxide containing at least one dopant selected from Al, Zr, and Si and having a ferroelectric non-centrosymmetric orthorhombic phase), zirconium oxide, hafnium-zirconium oxide, bismuth ferrite, barium titanate (e.g., BaTiO₃ (BT)), colemanite (e.g., Ca₂BO₁₁·5H₂O), bismuth titanate (e.g., Bi₄Ti₃O₁₂), europium barium titanate, ferroelectric polymer, germanium telluride, langbeinite (e.g., M₂M′₂(SO₄)₃ in which M is a monovalent metal and M′ is a divalent metal), lead scandium tantalate (e.g., Pb(ScₓTa₁₋ₓ)O₃), lead titanate (e.g., PbTiO₃ (PT)), lead zirconate titanate (e.g., Pb(Zr,Ti)O₃ (PZT)), lithium niobate (e.g., LiNbO₃ (LN)), lanthanum aluminate (LaAlO₃), polyvinylidene fluoride ((CH₂CF₂)ₙ), potassium niobate (e.g., KNbO₃), potassium sodium tartrate (e.g., KNaC₄H₄O₆·4H₂O), potassium titanyl phosphate (e.g., KO₅PTi), sodium bismuth titanate (such as Na_{0.5}Bi_{0.5}TiO₃ or Bi_{0.5}Na_{0.5}TiO₃), lithium tantalate (such as LiTaO₃ (LT)), lead lanthanum titanate (e.g., (Pb,La)TiO₃(PLT)), lead lanthanum zirconate titanate (e.g., (Pb,La)(Zr,Ti)O₃ (PLZT)), ammonium dihydrogen phosphate (such as NH₄H₂PO₄(ADP)), or potassium dihydrogen phosphate (e.g., KH₂PO₄ (KDP)). The ferroelectric layer 280 may be deposited using any suitable process, such as ALD, CVD, PVD, the like, or combinations thereof.

A ferroelectric memory device is a memory device containing the ferroelectric material as a memory material to store information. A ferroelectric material refers to a material that displays spontaneous polarization of electrical charges (e.g., dipoles) in the absence of an applied electric field. The dipole moment of the ferroelectric material is programmed in two different orientations (e.g., “up” or “down” polarization positions based on atom positions, such as oxygen and/or metal atom positions, in the crystal lattice), depending on the polarity of the applied electric field, to store information in the ferroelectric material. The different orientations of the dipole moment of the ferroelectric material may be detected by the electric field generated by the dipole moment of the ferroelectric material. In the present embodiments, the semiconductor structure 200A relies on the ferroelectric layer 280 to store information in a plurality of non-volatile memory devices (described in detail below) with different polarities (NMOS and PMOS). The compact and stackable design allows the semiconductor structure 200A to have multibit functionality.

Still referring to FIGS. 1C and 12A-12C, the method 100 at operation 132 deposits a third metal layer 284 over the ferroelectric layer 280 to fill each opening 269 and the gate regions 211A-211C, resulting in gate structures 270A, 270B, and 270C interleaved with the channel layers 220 in the respective active structures 207A-207D. In the present embodiments, the active structures 207B and 207C share the same gate structure 270B.

The third metal layer 284 may include any suitable conductive material (e.g., a metal), such as tungsten, copper, aluminum, ruthenium, cobalt, silver, gold, molybdenum, titanium, silver, manganese, zirconium, TiN, TaN, WN, ZrSi₂, MoSi₂, TaSi₂, NiSi₂, TaAl, TaAlC, TiAlN, TaC, TaCN, TaSiN, the like, or combinations thereof. In some embodiments, the third metal layer 284 includes a work function metal. In some embodiments, the third metal layer 284 and the second metal layer 276 have the same composition. In some embodiments, the third metal layer 284 and the second metal layer 276 have different compositions. The third metal layer 284 may be deposited using any suitable process, such as ALD, CVD, PVD, electroplating, electroless plating, the like, or combinations thereof. One or more CMP processes are subsequently performed to planarize the gate dielectric layer 272, the second metal layer 276, the ferroelectric layer 280, and the third metal layer 284.

In some embodiments, compositions of the second metal layer 276 and the third metal layer 284 are selected to achieve a work function corresponding to a suitable threshold voltage for each of the gate structures 270A-270C. In some embodiments, compositions of the second metal layer 276 and/or the third metal layer 284 of the gate structures 270A-270C are selected independently such that the threshold voltages for the gate structures 270A-270C can be tuned to different values corresponding to devices of different conductivity types. In this regard, the gate structures 270A-270C may be configured to provide transistors (e.g., field-effect transistors or FETs) of different conductivity types, such as n-type transistors (NMOS) or p-type transistors (PMOS).

Referring to FIGS. 1C, 13A-13C, and 14, the method 100 at operation 134 forms an isolation structure 288 through each of the gate structures 270A-270C.

In some embodiments, forming the isolation structures 288 includes first patterning the gate structures 270A-270C to form openings (not depicted). The gate structures 270A-270C may be patterned using the photolithography and etching techniques similar to the patterning of the stack 203. For example, a photoresist layer (not depicted) is deposited over the semiconductor structure 200A, irradiated, and developed to form a patterned photoresist layer, which exposes portions of the gate structures 270A-270C. The gate structures 270A-270C are then etched using the patterned photoresist layer as an etch mask, resulting in the openings through the gate structures 270A-270C. In some embodiments, multiple etching processes involving multiple etchants are implemented to etch the various material layers included in the gate structures 270A-270C.

Subsequently, a dielectric layer is deposited over the semiconductor structure 200A, thereby filling the openings in the gate structures 270A-270C. The dielectric layer may include an oxide, a nitride, a low-k dielectric material, the like, or combinations thereof. The dielectric layer may be deposited using any suitable method, such as CVD, HDP-CVD, FCVD, the like, or combinations thereof. In some embodiments, the dielectric layer has a composition similar to or the same as that of the first mask layer 218. A CMP process is then performed to remove a top portion of the dielectric layer and expose top surfaces of the gate structures 270A-270C, each including the isolation structure 288 embedded therein. The patterned photoresist layer is subsequently removed by a suitable method described above.

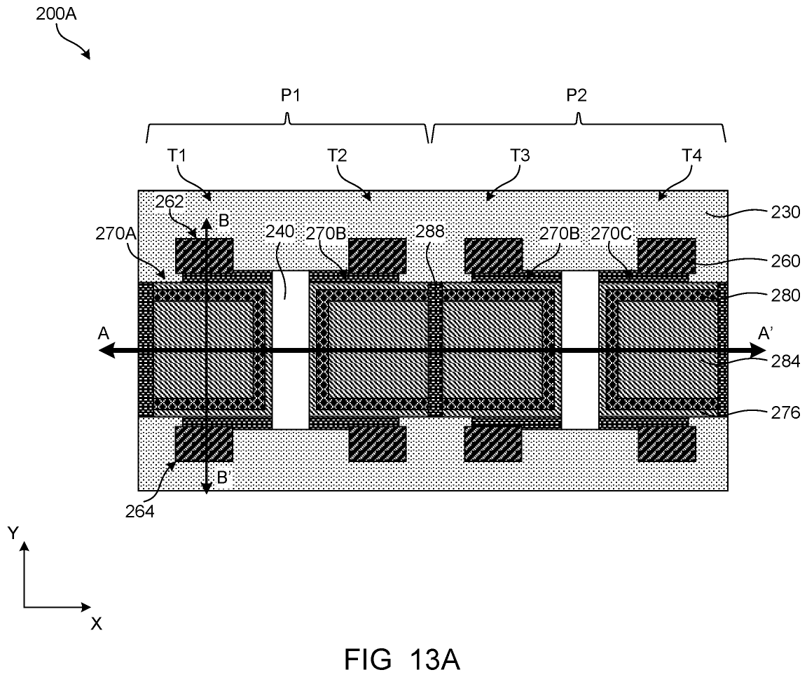

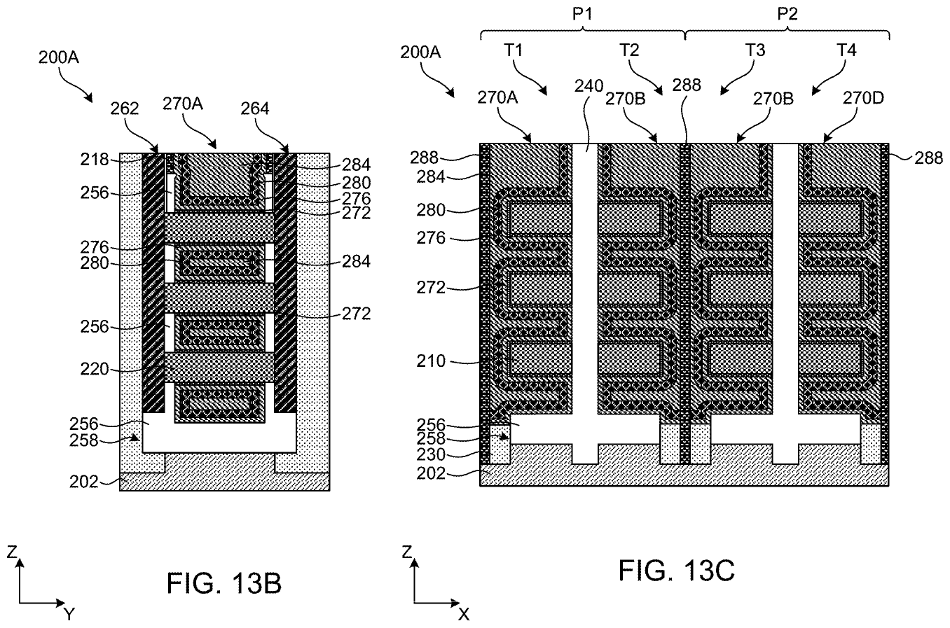

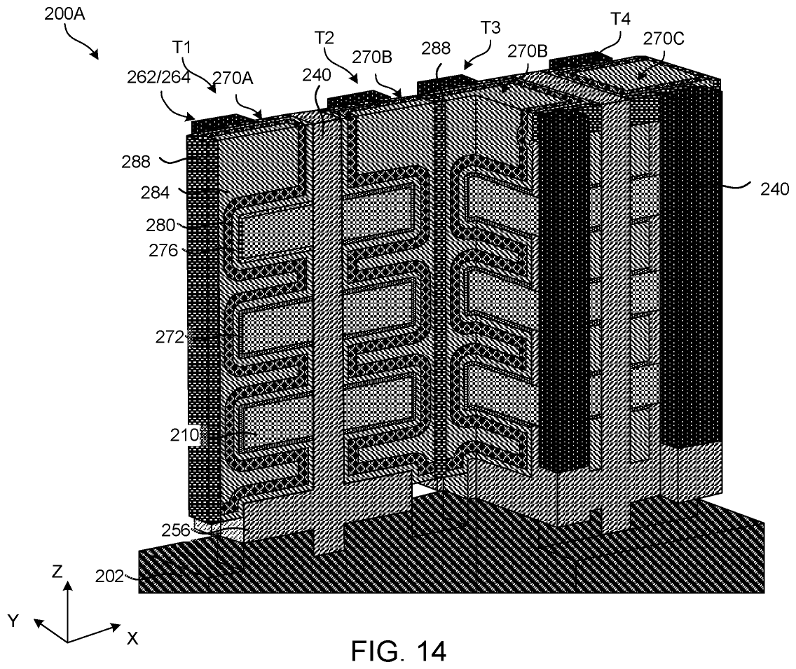

In the present embodiments, the isolation structures 288 each define a pair of memory devices (e.g., transistors) that are isolated by the second dielectric layer 240 extending along the Z direction. Referring to FIGS. 13A, 13C, and 14, the semiconductor structure 200A includes a first pair P1 of transistors adjacent a second pair P2 of transistors separated from the first pair P1 by the isolation structure 288. The first pair P1 includes a first transistor T1 and a second transistor T2 separated from the first transistor T1 by the second dielectric layer 240. Similarly, the second pair P2 includes a third transistor T3 and a fourth transistor T4 separated from the third transistor T3 by the second dielectric layer 240. In other words, a portion of the gate structure 270A engages with the active structure 207A to form the first transistor T1, a first portion of the gate structure 270B engages with the active structure 207B to form the second transistor T2, a second portion of the gate structure 270B engages with the active structure 207C to form the second transistor T3, and a portion of the gate structure 270C engages with the active structure 207D to form the second transistor T4. In the present embodiments, each of the transistors T1-T4 is configured as a forksheet transistor.

In some embodiments, the transistors T1-T4 are configured as ferroelectric memory devices, such as static random-access memory (SRAM) devices. In some embodiments, the transistors of each of the first pair P1 and the second pair P2 are configured to have different conductivity types (or polarities), i.e., as an NMOS device and a PMOS device, respectively. In this regard, the first pair P1 and the second pair P2 are each configured as a complementary MOS, or CMOS, device. In some embodiments, the transistors of each of the first pair P1 and the second pair P2 are configured to have the same conductivity types, i.e., as two NMOS devices or two PMOS devices.

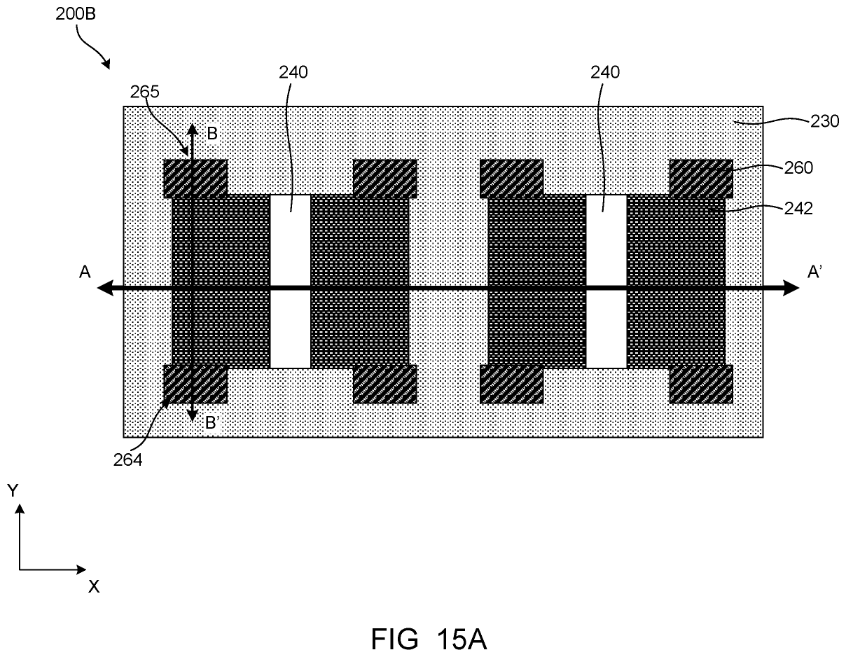

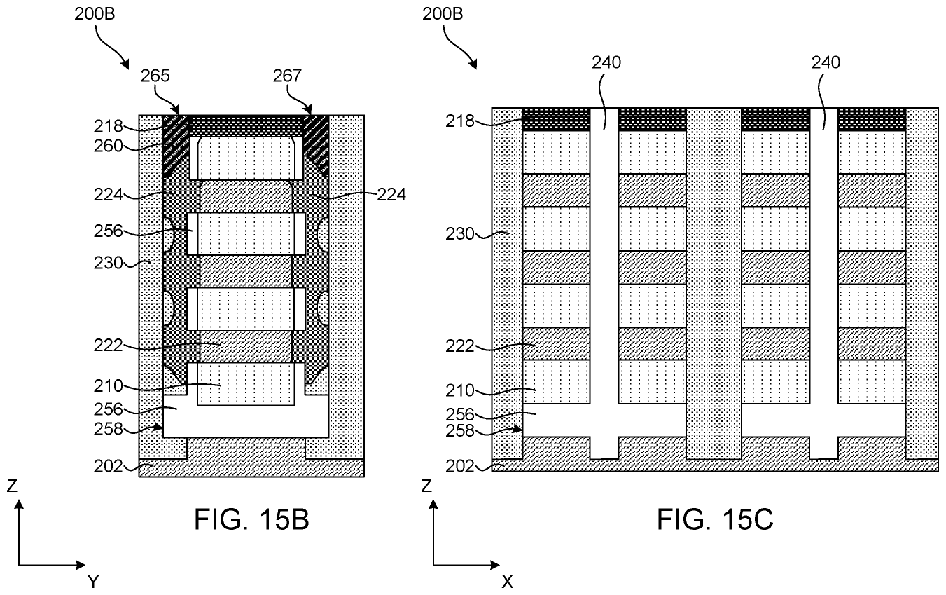

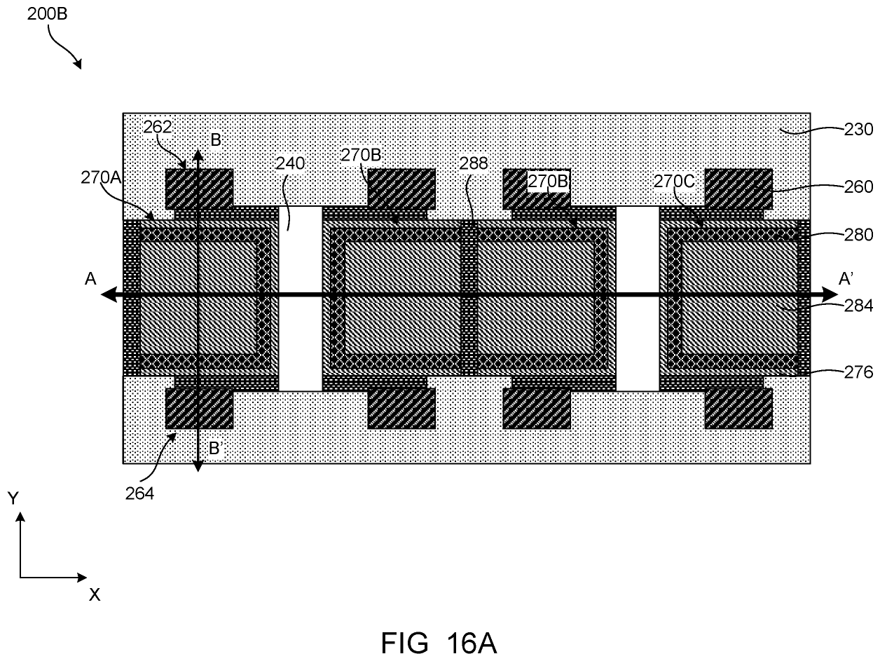

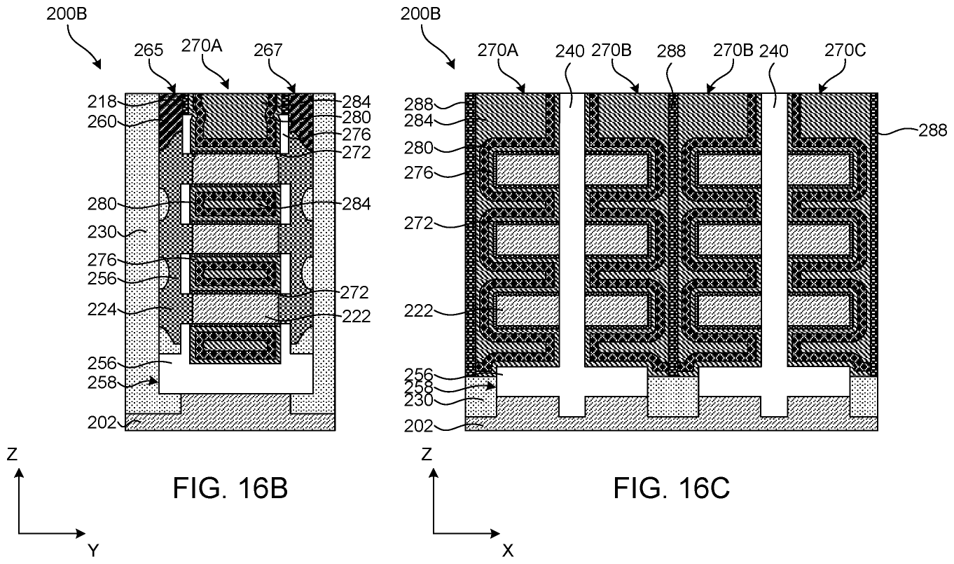

Referring to FIGS. 15A-16C collectively, a semiconductor structure 200B is depicted. The semiconductor structure 200B is substantially similar to the semiconductor structure 200A with the exception that instead of including a doped semiconductor material in the channel layers 220, the semiconductor structure 200B includes channel layers 222 containing an un-doped (or intrinsic) semiconductor material, such as un-doped silicon. In this regard, doped semiconductor layers may be epitaxially grown over sidewalls of the channel layers 222 before forming the first metal layer 260. For example, after etching the third dielectric layer 256 to expose the S/D regions 209A-209D at operation 116, the method 100 at operation 117 (of FIG. 1B) forms a doped semiconductor layer 224 over each sidewall of the channel layer 222 in the S/D regions 209A-209B, as depicted in FIGS. 15A-15C. As such, the doped semiconductor layer 224 is configured as an S/D feature (or S/D structure) that couples the channel layer 222 to the subsequently formed first metal layer 260, which serves as an S/D contact, over a top surface of the doped semiconductor layer 224 and a top portion of the sidewalls of the active structures 207A-207D.

The doped semiconductor layer 224 includes a suitable dopant, such as an n-type dopant or a p-type dopant, selected according to the type of device to be formed. For example, the doped semiconductor layer 224 may include silicon doped with an n-type dopant, such as phosphorous and/or arsenic. In some embodiments, the doped semiconductor layer 224 includes multiple layers of material having different dopant concentrations.

As depicted in FIG. 15B, the doped semiconductor layer 224 is epitaxially grown outwardly from each channel layer 222 along the Y direction (e.g., laterally) and extend along the Z direction (e.g., vertically) to cover sidewalls of the third dielectric layer 256. In some embodiments, the doped semiconductor layer 224 is formed by a suitable process similar to the process of forming the second sacrificial layer 204 and the stack 203, such as by MBE, CVD (e.g., MOCVD), the like, or combinations thereof. The dopant may be introduced during the epitaxial growth (e.g., an in-situ doping process) or implanted after the epitaxial growth is completed. In the case of the latter scenario, end portions of the channel layer 222 may also be doped such that the doped semiconductor layer 224 extends inwardly from one sidewall of the channel layer 222 toward an opposite sidewall along the Y direction.

Subsequently, still referring to FIGS. 15A-15C, the method 100 at operation 118 forms the first metal layer 260 over the doped semiconductor layer 224 to form a first electrode (e.g., a first S/D electrode) 265 and a second electrode (e.g., a second S/D electrode) 267. Different from the embodiment depicted in FIGS. 8A-8D, the first metal layer 260 depicted in FIG. 15B is formed over a top surface of the doped semiconductor layer 224 rather than along the sidewalls of the channel layers 222. In this regard, the first metal layer 260 does not directly contact the channel layers 222 such that a sidewall of the first metal layer 260 (e.g., the first electrode 265 and the second electrode 267) is vertically aligned with a sidewall (or portions thereof) of the doped semiconductor layer 224.

Thereafter, referring to FIGS. 16A-16C, the method 100 proceeds to operations 120-134 (of FIGS. 1B and 1C), which include removing the first sacrificial layers 210, forming the gate structures 270B-270C, and isolating adjacent transistors T1-T4 as described above in reference to FIGS. 9A-14.

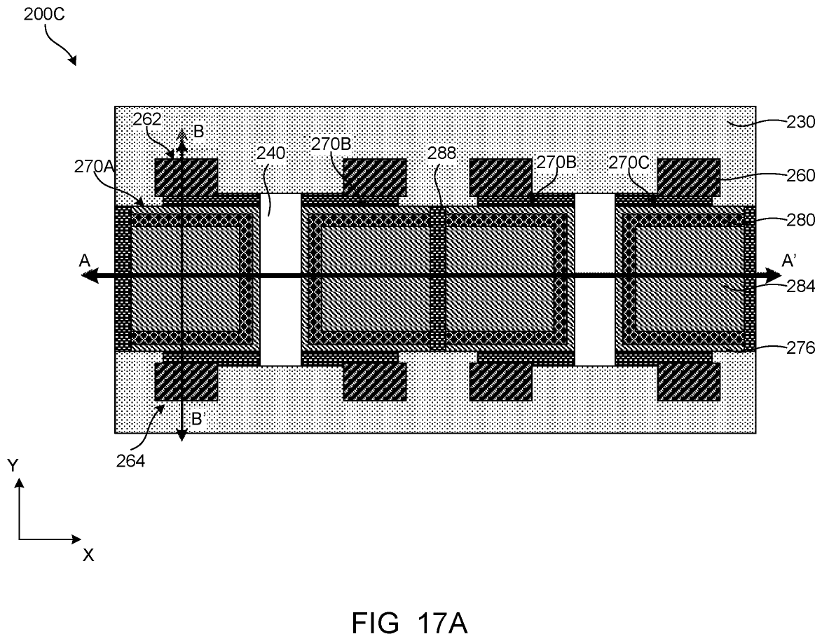

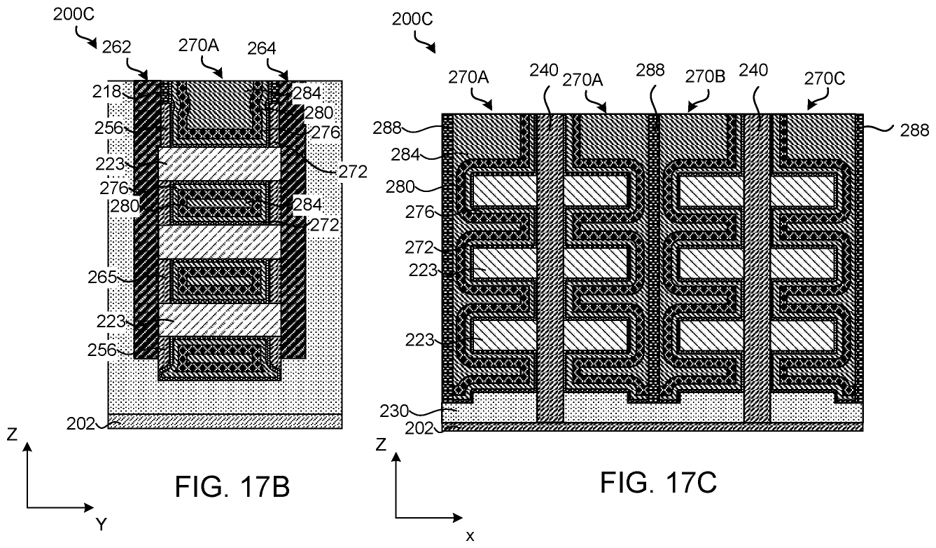

Referring to FIGS. 17A-17C, a semiconductor structure 200C is depicted. The semiconductor structure 200C is similar to the semiconductor structure 200A (and 200B) with the exception that, instead of including a doped semiconductor material in the channel layers 220, the semiconductor structure 200C includes channel layers 223 containing a conductive oxide described above. The channel layers 223 are formed to interleave with the first sacrificial layers 210 in the stack 203 at operation 102. The channel layers 223 may be deposited by a suitable process, such as CVD, ALD, PVD, the like, or combinations thereof, over each first sacrificial layer 210.

In the present embodiments, the semiconductor structure 200C further differs from the semiconductor structure 200A (and 200B) in that the semiconductor structure 200C does not include the isolation structure 258, which includes the third dielectric layer 256, between the bottommost portion of each gate structure 270A-270C and the semiconductor substrate 202. Instead, a portion of the first dielectric layer 230 is interposed between a bottom surface of each gate structure 270A-270C and the semiconductor substrate 202. In some embodiments, the semiconductor structure 200C may include more than one active structures (e.g., the active structures 207A-207D) stacked over one another along the Z direction.

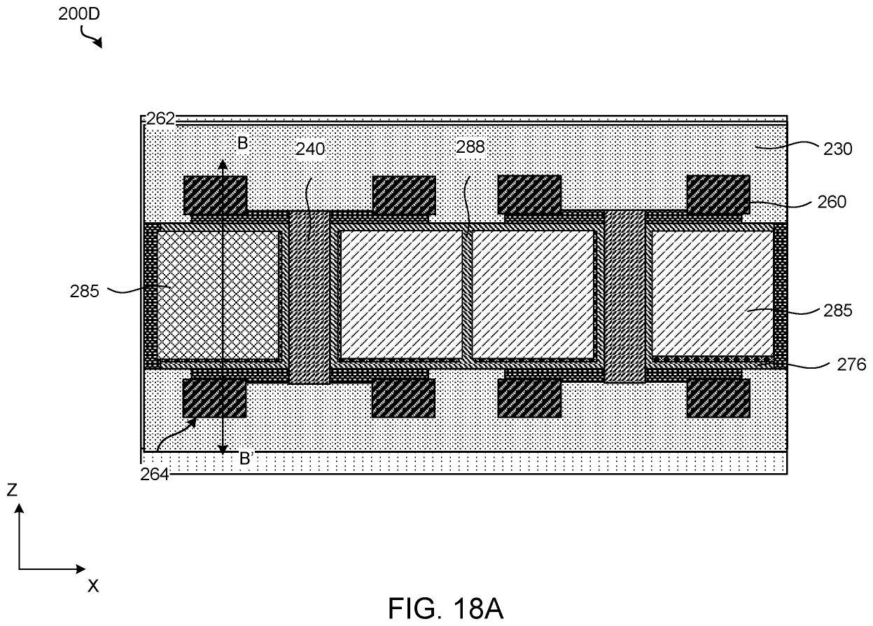

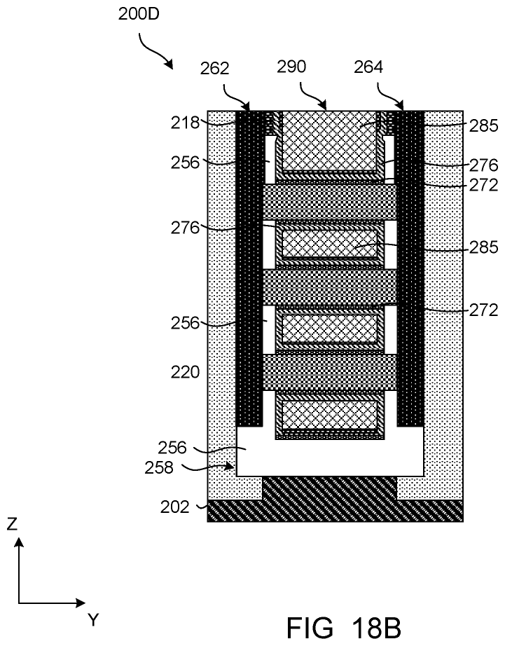

In some embodiments, referring to FIGS. 18A and 18B, a semiconductor structure 200D is depicted. The semiconductor structure 200D is similar to the semiconductor structure 200A with the exception that the semiconductor structure 200D includes a gate structure 290 that differs from the gate structure 270A-270C. For example, the gate structure 290 includes a fourth metal layer 285 and the second metal layer 276 over the gate dielectric layer 272 and does not include a ferroelectric layer (e.g., the ferroelectric layer 280) between the two metal layers. In this regard, the semiconductor structure 200D may provide a logic device (e.g., transistor) rather than a memory device as is the case for each of the transistors T1-T4 provided herein. The fourth metal layer 285 may be similar to the second metal layer 276 and/or the third metal layer 284 in composition.

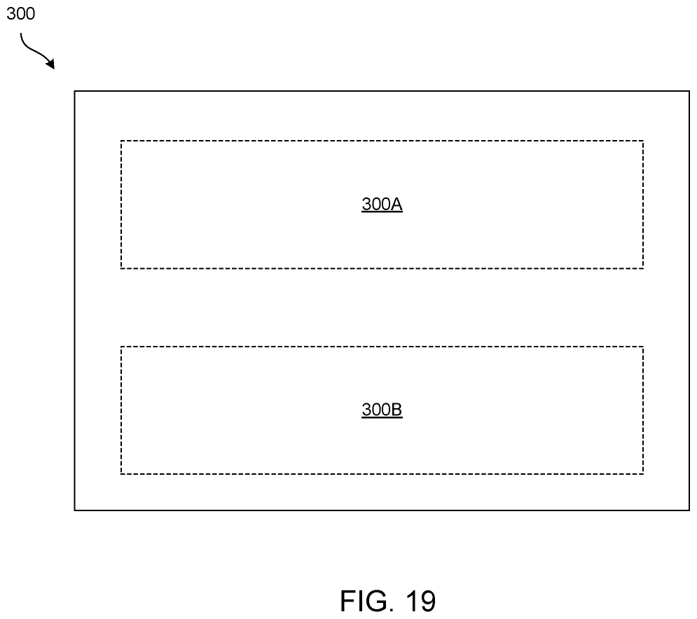

In some embodiments, referring to FIG. 19, a planar top view of a semiconductor structure 300 is depicted. The semiconductor structure 300 includes a first region 300A and a second region 300B, where the first region 300A and the second region 300B are configured to provide devices of different functions and structures. In some embodiments, the first region 300A includes a plurality of memory devices (e.g., non-volatile ferroelectric memory devices), such as one or more of the semiconductor structures 200A-200C provided herein. In some embodiments, the second region 300B includes a plurality of logic devices, such as the semiconductor structure 200D provided herein. In some examples, logic devices of the second region 300B are configured as portions of a peripheral circuitry integrated with an array of the memory devices of the first region 300A. In some embodiments, though not depicted, the semiconductor structure 300 includes a memory device), such as one of the semiconductor structures 200A-200C, stacked over a logic device, such as the semiconductor structure 200D, along the Z direction. For example, the semiconductor structure 300 may include the semiconductor structure 200C stacked over the semiconductor structure 200D along the Z direction.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A memory device, comprising:
a stack of channel layers extending vertically over a substrate;
a gate structure interleaved with the stack, wherein the gate structure wraps around a first end of each channel layer, the gate structure including:
a dielectric layer over the channel layer;
a ferroelectric layer over the dielectric layer; and
a metal layer over the ferroelectric layer; and
an isolation structure disposed over a second end of each channel layer opposite the first end.

2. The memory device of claim 1, wherein the channel layers include a doped semiconductor material or a conductive oxide material.

3. The memory device of claim 2, further comprising:
a first electrode extending along a first sidewall of the stack and coupled to a third end of each channel layer; and
a second electrode extending along a second sidewall of the stack opposite the first sidewall and coupled to a fourth end of each channel layer opposite the third end.

4. The memory device of claim 2, wherein the channel layers include the doped semiconductor material and the isolation structure is a first isolation structure, the memory device further comprising a second isolation structure disposed between a bottom surface of the gate structure and the substrate.

5. The memory device of claim 1, wherein the channel layers include a semiconductor material free of a dopant.

6. The memory device of claim 5, wherein the isolation structure is a first isolation structure, the memory device further comprising:
a first doped semiconductor layer disposed over a third end of each channel layer;
a second doped semiconductor layer disposed over a fourth end of each channel layer opposite the third end;
a first electrode coupled to a top surface of the first doped semiconductor layer;
a second electrode coupled to a top surface of the second doped semiconductor layer; and
a second isolation structure disposed between a bottom surface of the gate structure and the substrate.

7. The memory device of claim 1, further comprising spacers disposed over sidewalls of the gate structure between two adjacent channel layers along a vertical direction.

8. The memory device of claim 1, wherein the metal layer is a first metal layer, and wherein the gate structure further includes a second metal layer disposed between the dielectric layer and the ferroelectric layer.

9. A semiconductor structure, comprising:
a memory device, including:
first channel layers stacked vertically over a substrate;
a first gate structure interleaved with the first channel layers, wherein the first gate structure wraps around a first end of each first channel layer, the first gate structure including:
a first gate dielectric layer over the first channel layer;
a first metal layer over the first gate dielectric layer;
a ferroelectric layer over the first metal layer; and
a second metal layer over the ferroelectric layer; and
a first dielectric layer extending vertically over a second end of each first channel layer opposite the first end.

10. The semiconductor structure of claim 9, wherein the first channel layers include a doped semiconductor material or a conductive oxide material.

11. The semiconductor structure of claim 10, wherein the memory device further includes a first source/drain electrode and a second source/drain electrode coupled to a third end and a fourth end of each first channel layer, respectively, the third end and the fourth end being opposite of one another.

12. The semiconductor structure of claim 10, wherein the first channel layers include the doped semiconductor material, the memory device further comprising a second dielectric layer interposed between a bottom surface of the gate structure and the substrate.

13. The semiconductor structure of claim 9, wherein the first channel layers include an intrinsic semiconductor material, and wherein the memory device further includes:
a first doped source/drain feature and a second doped source/drain feature coupled to a third end and a fourth end of each first channel layer, respectively, the third end and the fourth end being opposite of one another; and
a second dielectric layer interposed between a bottommost first channel layer and the substrate.

14. The semiconductor structure of claim 13, wherein the memory device further includes a first electrode and a second electrode coupled to the first doped source/drain feature and the second doped source/drain feature, respectively.

15. The semiconductor structure of claim 9, further comprising a logic device adjacent the memory device, the logic device including:
second channel layers stacked vertically over the substrate;
a second gate structure interleaved with the second channel layers, wherein the second gate structure wraps around a first end of each second channel layer, the second gate structure including:
a second gate dielectric layer over the second channel layer; and
a third metal layer over the second gate dielectric layer, wherein the second gate structure is free of the ferroelectric layer; and
a second dielectric layer extending vertically over a second end of each second channel layer opposite the first end.

16. A method, comprising:
forming a stack including alternating first sacrificial layers and channel layers over a second sacrificial layer on a substrate;
forming a first dielectric layer adjacent each sidewall of the stack;
patterning the stack to form a first opening vertically extending through the stack to form first active structure adjacent a second active structure;
forming a second dielectric layer to fill the first opening;
selectively etching end portions of the first sacrificial layer to form second openings;
forming a third dielectric layer to fill the second openings;
etching the third dielectric layer to expose portions of each sidewall of the first active structure and the second active structure;
forming a metal layer to at least partially cover the sidewall of the first active structure and the second active structure, the metal layer being coupled to end portions of each channel layer;
selectively removing the first sacrificial layers to form third openings; and
forming a gate structure in the third openings, the gate structure including a ferroelectric layer.

17. The method of claim 16, wherein the channel layers include a doped semiconductor material or an intrinsic semiconductor material, wherein selectively etching the end portions of the first sacrificial layers removes the second sacrificial layer to form a fourth opening, and wherein forming the third dielectric layer forms an isolation structure in the fourth opening.

18. The method of claim 16, wherein the channel layers include an intrinsic semiconductor material, the method further comprising epitaxially growing a doped semiconductor layer from each of the end portions of the channel layer before forming the first metal layer, wherein the doped semiconductor layer is grown over a sidewall of the third dielectric layer, and wherein the metal layer is formed over a top portion of the sidewall of each of the first active structure and the second active structure such that the first metal layer is coupled to a top surface of the doped semiconductor layer.

19. The method of claim 16, wherein the channel layers include a doped semiconductor material or a conductive oxide material.

20. The method of claim 16, wherein the metal layer is a first metal layer, and wherein forming the gate structure includes:
forming a gate dielectric layer over each channel layer;
forming a second metal layer over the gate dielectric layer;
forming the ferroelectric layer over the gate dielectric layer; and
forming a third metal layer over the ferroelectric layer.
